(19) United States
(12) Patent Application Publication
(10) Pub. No.: US 2025/0227930 A1
(43) Pub. Date: Jul. 10, 2025

(54) SEMICONDUCTOR DEVICES, ELECTRONIC SYSTEMS INCLUDING THE SAME, AND MANUFACTURING METHODS THEREOF

(71) Applicant: Samsung Electronics Co., Ltd., Suwon-si (KR)

(72) Inventors: Minju LEE, Suwon-si (KR); Daihong KIM, Suwon-si (KR); Sangho RHA, Suwon-si (KR); Seungjae SIM, Suwon-si (KR); Kyung-Tae JANG, Suwon-si (KR); Mingyu JEON, Suwon-si (KR)

(21) Appl. No.: 18/768,103

(22) Filed: Jul. 10, 2024

(30) Foreign Application Priority Data
Jan. 9, 2024 (KR) 10-2024-0003492

(51) Int. Cl. H10B 43/27; H10B 43/35; H10B 43/40

(52) U.S. Cl. CPC H10B 43/27; H10B 43/35; H10B 43/40

(57) ABSTRACT

A semiconductor device comprising: a substrate; a circuit region on the substrate; and a cell region on the circuit region, wherein the cell region includes a cell array region and a connection region, wherein the cell region further includes: a gate stacking structure including interlayer insulating layers and gate electrodes alternately stacked on the substrate; a channel structure extending in the gate stacking structure in the cell array region; a gate contact part electrically connected to the gate electrodes of the gate stacking structure in the connection region; and an auxiliary layer in contact with the gate stacking structure in the connection region, wherein the gate stacking structure has a step structure in a cross-sectional view in the connection region, the auxiliary layer is at a corner of the step structure, the auxiliary layer has a curved surface, and the auxiliary layer includes boron, phosphorus, nitrogen, and/or iron.

### CROSS-REFERENCE TO RELATED APPLICATIONS

This application claims priority to and the benefit of Korean Patent Application No. 10-2024-0003492 filed in the Korean Intellectual Property Office on Jan. 9, 2024, the entire contents of which are incorporated herein by reference.

### BACKGROUND OF THE INVENTION

### Field of the Invention

The present disclosure relates to semiconductor devices with a stacked structure.

### Description of the Related Art

A semiconductor is a material that belongs to an (electrically) intermediate region between the conductor and the insulator and means a material that conducts electricity under a predetermined condition. Various semiconductor devices may be manufactured using such a semiconductor material, and for example, memory devices and the like may be manufactured. The memory devices may be divided into volatile memory devices and non-volatile memory devices. In the case of non-volatile memory devices, even if the power is cut off, the contents (stored in the non-volatile memory devices) may not be deleted, and may be used in various electronic devices such as mobile phones, digital cameras, and PCs, and the like.

According to the recent trend of increasing storage capacity, non-volatile memory devices are in need of improving (e.g., increasing) integration density. The integration density of the memory devices (e.g., the non-volatile memory devices), which are two-dimensionally arranged in a plane, may be limited. Accordingly, vertical non-volatile memory devices which are three-dimensionally arranged have been proposed.

### SUMMARY OF THE INVENTION

Embodiments herein provide semiconductor devices with improved reliability and productivity and electronic systems including the semiconductor devices. A semiconductor device comprising: a substrate; a circuit region that includes a peripheral circuit structure on the substrate; and a cell region on the circuit region, wherein the cell region includes a cell array region and a connection region adjacent the cell array region, wherein the cell region further includes: a gate stacking structure that includes interlayer insulating layers and gate electrodes that are alternately stacked on the substrate; a channel structure that extends in the gate stacking structure in the cell array region; a gate contact part that is electrically connected to the gate electrodes of the gate stacking structure in the connection region; and an auxiliary layer that is in contact with the gate stacking structure in the connection region, wherein the gate stacking structure has a step structure in a cross-sectional view in the connection region, wherein the auxiliary layer is at a corner of the step structure, wherein the auxiliary layer has a curved surface, and wherein the auxiliary layer includes a first material that includes boron, phosphorus, nitrogen, and/or iron.

The semiconductor device manufacturing method according to some embodiments includes forming a stacking structure by alternately stacking sacrificial insulating layers and insulating layers in a circuit region that includes a peripheral circuit structure; depositing an auxiliary layer on an upper surface of the stacking structure; heat-treating the auxiliary layer to alleviate an angle of the auxiliary layer; and etching the auxiliary layer, wherein a part of the auxiliary layer includes a curved surface at a corner of the stacking structure. An electronic system comprising: a main substrate; a semiconductor device on the main substrate; and a controller electrically connected to the semiconductor device on the main substrate, wherein the semiconductor device includes: a substrate; a circuit region that includes a peripheral circuit structure on the substrate; and a cell region on the circuit region, wherein the cell region includes a cell array region and a connection region adjacent the cell array region, wherein the cell region further includes: a gate stacking structure that includes interlayer insulating layers and gate electrodes that are alternately stacked on the substrate; a channel structure that extends in the gate stacking structure in the cell array region; a gate contact part that is electrically connected to the gate electrodes of the gate stacking structure in the connection region; and an auxiliary layer that is in contact with the gate stacking structure in the connection region, wherein the gate stacking structure has a step structure in a cross-sectional view in the connection region, and wherein the auxiliary layer is at a corner of the step structure, wherein the auxiliary layer has a curved surface, and wherein the auxiliary layer includes a material that includes boron, phosphorus, nitrogen, and/or iron. According to embodiments, semiconductor devices and electronic systems including the semiconductor devices with improved reliability and productivity are provided.

### BRIEF DESCRIPTION OF THE DRAWINGS

FIG. 1 is a cross-sectional view illustrating a semiconductor device according to some embodiments.

FIG. 2 is a cross-sectional view illustrating a channel structure included in the semiconductor device illustrated in FIG. 1.

FIG. 3 is an enlarged view of the part R3 in FIG. 1.

FIG. 4 is an enlarged view of the part R2 in FIG. 1.

FIGS. 5 to 7 are schematic diagrams briefly illustrating the forming process of an auxiliary layer having a curved surface according to some embodiments.

FIG. 8 is a schematic diagram illustrating the forming process of the connection region insulating layer when the auxiliary layer is not formed.

FIG. 9 is a schematic diagram illustrating the forming process of the connection region insulating layer when the auxiliary layer is formed.

FIG. 10 is a cross-sectional view schematically illustrating a semiconductor device according to some embodiments.

FIG. 11 is a cross-sectional view schematically illustrating a semiconductor device according to some embodiments.

FIGS. 12 to 21 are cross-sectional views illustrating the manufacturing method for a semiconductor device according to some embodiments.

FIG. 22 is a schematic view illustrating an electronic system including a semiconductor device according to some embodiments.

FIG. 23 is a perspective view schematically illustrating an electronic system including a semiconductor device according to some embodiments.

FIGS. 24 and 25 are cross-sectional views schematically illustrating a semiconductor package according to some embodiments.

### DETAILED DESCRIPTION OF THE INVENTION

Hereinafter, with reference to the accompanying drawing, several embodiments of the present disclosure will be described in detail so that a person of an ordinary skill can easily practice it in the technical field to which the present disclosure belongs. The present disclosure may be implemented in several different forms and is not limited to the embodiments described herein.

In order to clearly explain the present disclosure, parts that do not have a relationship with the explanation may be omitted, and identical or similar components are assigned the same reference numerals throughout the specification unless clearly stated otherwise.

In addition, the size and thickness of each component shown in the drawing are arbitrarily shown (in terms of scale) for better understanding and ease of description, so the present disclosure is not necessarily limited to what is shown. For example, in the drawing, thicknesses may be enlarged in order to clearly express several layers and regions.

And in the drawings, for the convenience of explanation, the thickness of some layers and regions may be exaggerated. In addition, when an element such as a layer, film, region, or substrate is referred to as being “above” or “on” another element, this may include not only the case where the other element is “directly on” but also the case where there is other element therebetween. In contrast, when an element is referred to as being “directly on” other element, it means that there is no other element therebetween. In addition, being “above” or “on” a reference part means being positioned above or below the reference part and does not necessarily mean being positioned “above” or “on” is being in the opposite direction of gravity.

In addition, when a part “includes” a component throughout the specification, this means other components may be further included, rather than excluding other components unless otherwise stated.

In addition, throughout the specification, when it comes to “in a plane,” it means when the target part is viewed from above, and when it comes to “cross-section,” it means when the cross-section of the target part is vertically cut from the side.

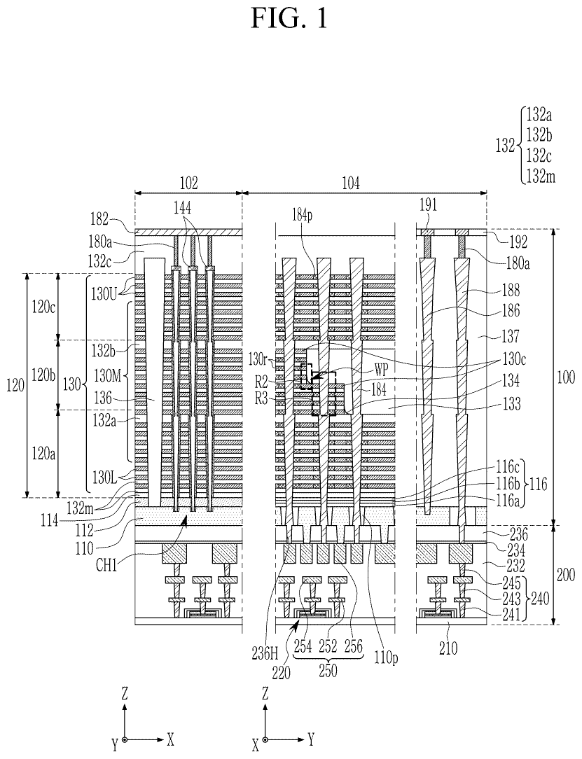

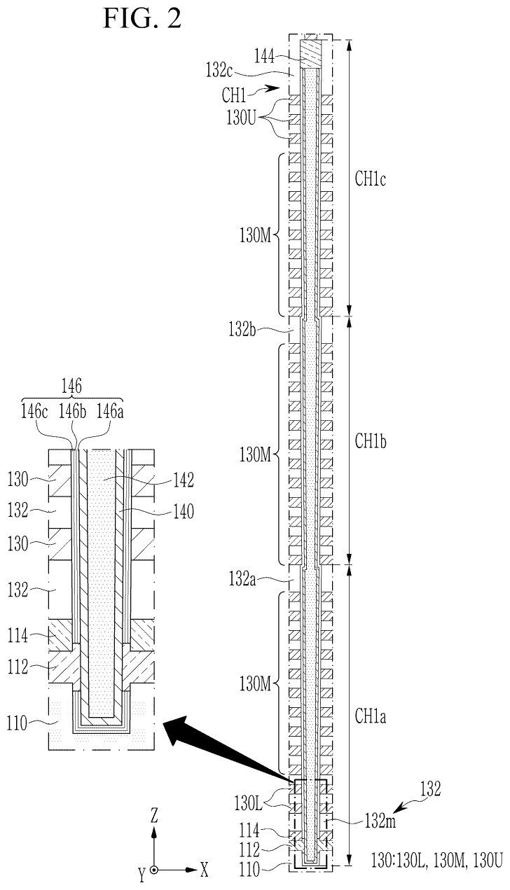

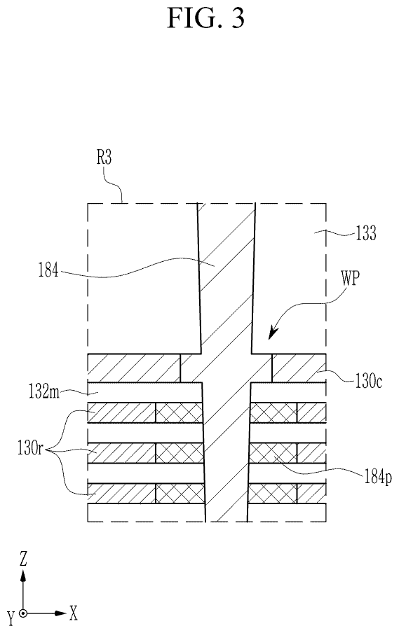

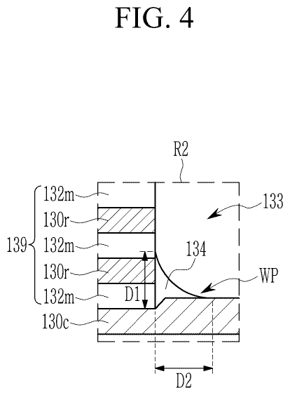

FIG. 1 is a cross-sectional view illustrating a semiconductor device according to some embodiments. FIG. 2 is a cross-sectional view illustrating a channel structure included in the semiconductor device illustrated in FIG. 1. FIG. 3 is an enlarged view of the part R3 in FIG. 1. FIG. 4 is an enlarged view of the part R2 in FIG. 1.

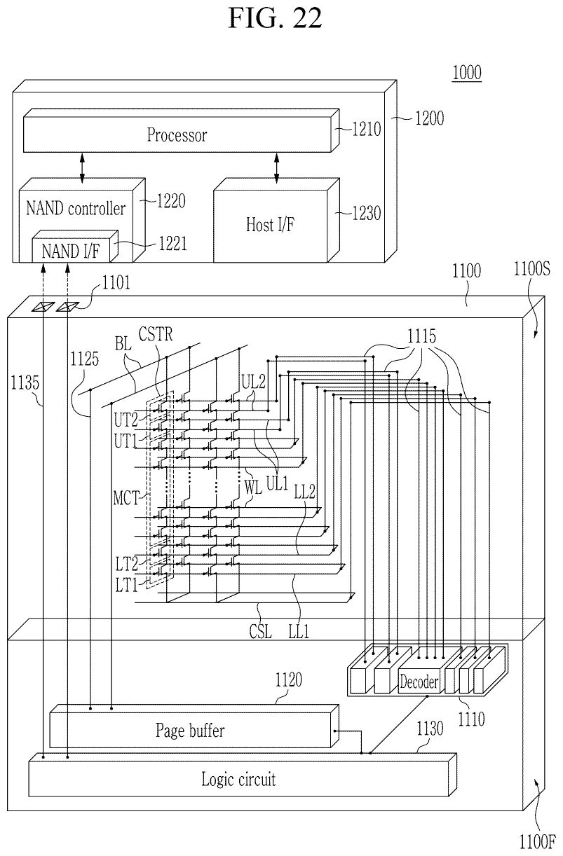

Referring to FIGS. 1 to 4, a semiconductor device according to some embodiments may include a cell region 100 including a memory cell structure and a circuit region 200 including a peripheral circuit structure that controls an operation of the memory cell structure. For example, the circuit region 200 and the cell region 100 may be parts corresponding to a first structure 1100F and a second structure 1100S of a semiconductor device 1100 included in an electronic system 1000 shown in FIG. 22, respectively.

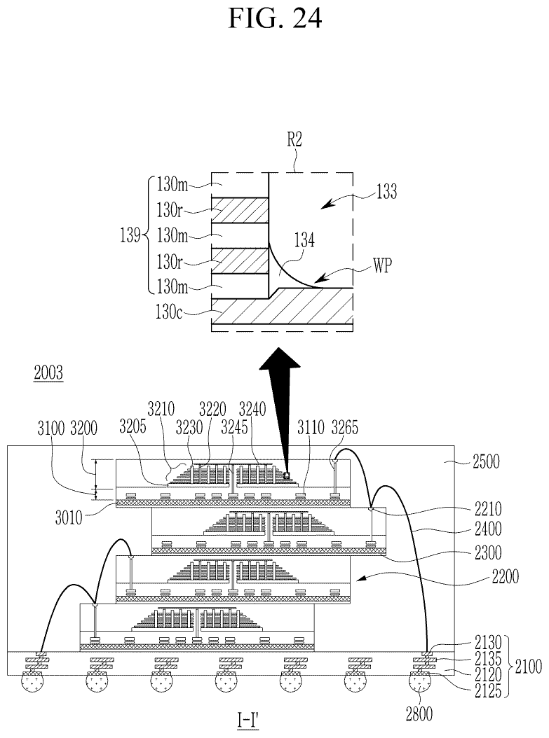

In some embodiments, the circuit region 200 and the cell region 100 may be parts corresponding to the first structure 3100 and the second structure 3200 of the semiconductor chip 2200 shown in FIG. 24, respectively. In some embodiments, the cell region 100 may be positioned above (on) the circuit region 200. Accordingly, the area corresponding to the circuit region 200 is not required separately from the cell region 100, thereby reducing the area of the semiconductor device. However, the arrangement relationship between the circuit region 200 and the cell region 100 is not limited thereto and may be variously changed. For example, the circuit region 200 may be positioned next to (adjacent) the cell region 100.

The circuit region 200 may include a first substrate 210, a circuit element 220, a lower conductive via 240, a lower wire 250, and circuit insulating layers 232, 234, and 236.

The first substrate 210 may be a semiconductor substrate including a semiconductor material. For example, the first substrate 210 may be a semiconductor substrate made of a semiconductor material, or a semiconductor substrate in which a semiconductor layer is formed on the base substrate. The first substrate 210 may include, for example, silicon, epitaxial silicon, germanium, silicon-germanium, silicon-on-insulator SOI, and/or germanium-on-insulator GOI.

The circuit element 220 positioned on the first substrate 210 may include various circuit elements that control an operation of the memory cell structure provided in the cell region 100. For example, the circuit element 220 may include a peripheral circuit structure such as a decoder circuit (e.g., 1110 in FIG. 22), a page buffer (e.g., 1120 in FIG. 22), and a logic circuit (e.g., 1130 in FIG. 22).

The circuit element 220 may include a transistor, but is not limited thereto. For example, the circuit element 220 may include not only an active element such as a transistor, but also a passive element such as a capacitor, a resistor, and an inductor.

The lower wire 250 positioned above (on) the first substrate 210 may be electrically connected to the circuit element 220. The lower wire 250 may include a plurality of first, second, and third lower wire layers 252, 254, and 256. The plurality of first, second, and third lower wire layers 252, 254, and 256 may be connected (e.g., electrically connected) to a plurality of lower conductive vias 241, 243, and 245 (of the lower conductive via 240). It will be understood that when an element or layer is referred to as being “connected to”, or “coupled to” “responsive to”, or “on” another element or layer, it may be directly connected to, directly coupled to, directly responsive to, or directly on the other element or layer, or one or more intervening elements or layers may be present. In contrast, when an element is referred to as being “directly coupled,” “directly connected,” or “directly responsive to”, or “directly on,” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present.

The first circuit insulating layer 232 may include the lower wire 250 and a via hole. The via hole may be (at least partially) filled with the lower conductive via 240. For example, the first circuit insulating layer 232 may include a plurality of insulating layers extending around the first, second, and third lower wire layers 252, 254, and 256 and the plurality of lower conductive vias 241, 243, and 245.

The lower conductive via 240 and the lower wire 250 may include a conductive material, and the first circuit insulating layer 232 may include an insulating material. For example, the lower conductive via 240 and the lower wire 250 may include a metal such as tungsten or the like, and the first circuit insulating layer 232 may include a silicon oxide, etc.

Although FIG. 1 illustrates that the lower wire 250 includes three wire layers 252, 254, and 256 and the lower conductive via 240 includes three vias 241, 243, and 245, it is only an example and is not limited thereto. Depending on the embodiments, the number of wire layers and vias may be 2 or less, or 4 or more.

The second circuit insulating layer 234 may be positioned on the first circuit insulating layer 232. In the process of forming the cell region 100 to be described later, the second circuit insulating layer 234 may reduce hydrogen from penetrating and diffusing into the circuit region 200 positioned beneath cell region 100. That is, the second circuit insulating layer 234 may play a role as a hydrogen blocking layer. The second circuit insulating layer 234 may include, for example, silicon nitride or the like.

The third circuit insulating layer 236 may be positioned above (on) the second circuit insulating layer 234. The third circuit insulating layer 236 may include a contact hole 236H for connecting the contact parts 184, 186, and 188 of the cell regions 100 to the third lower wire layer 256 of the circuit region 200 to be described later. The third circuit insulating layer 236 may include, for example, silicon oxide, and the like.

The cell region 100 may include a cell array region 102 and a connection region 104.

In the cell array region 102, a first channel structure CH1 and the gate stacking structure 120 may be positioned on the second substrate 110. In the cell array region 102 and/or the connection region 104, a structure for connecting (e.g., electrically connecting) the gate stacking structure 120 and/or the first channel structure CH1 positioned in the cell array region 102 to the circuit region 200 and/or an external circuit may be positioned. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

Specifically, the cell region 100 may include a second substrate 110, horizontal conductive layers 112, and 114, a horizontal insulating layer 116, a gate stacking structure 120, a first channel structure CH1, a separation structure 136, a bit line 182, a gate contact part 184, a source contact part 186, a through contact part 188, a contact via 180a connected (e.g., electrically connected) to the contact part 188, and a connection wire 191 connecting (e.g., electrically connecting) to the contact via 180a.

In an embodiment, the second substrate 110 may include a semiconductor material. For example, the second substrate 110 may be a semiconductor substrate made of a semiconductor material, or a semiconductor substrate in which a semiconductor layer is formed on the base substrate. For example, the second substrate 110 may include polysilicon doped with impurity. The second substrate 110 may perform a function as a common source line. The second substrate 110 may function as a source region for supplying current to the memory cells positioned on the second substrate 110. The second substrate 110 may be formed in a plate shape. That is, the second substrate 110 may be formed of a plate common source line.

In some embodiments, the second substrate 110 may include silicon, germanium, silicon-germanium, silicon-on-insulator, germanium-on-insulator, and/or the like. P-type and/or N-type impurity may be doped into (the semiconductor material included in) the second substrate 110. For example, N-type impurity (e.g., phosphorus (P), arsenic (As), etc.) may be doped. However, the conductivity type, material, etc. of impurity doped into (the semiconductor material in) the second substrate 110 are not limited thereto and may be variously changed.

The second substrate 110 may be connected (e.g., electrically connected) to the third lower wire layer 256 of the circuit region 200. That is, a portion of the second substrate 110 may be directly connected to the third lower wire layer 256 of the circuit region 200 through a contact hole 236H included in the third circuit insulating layer 236.

A substrate insulating pattern 110p may be positioned in the second substrate 110. The substrate insulating pattern 110p may be positioned in a region of the second substrate 110 where contact parts 184, 186, and 188 to be described later extend in (e.g., penetrate). That is, as the substrate insulating pattern 110p is positioned between the contact parts 184, 186, and 188 extending in (e.g., penetrating) the second substrate 110 and the second substrate 110, the contact parts 184, 186, and 188 may be separated and (electrically) insulated from the second substrate 110.

In the cell array region 102, a gate stacking structure 120 including a cell insulating layer 132 and a gate electrode 130 which are stacked on the first surface (e.g., the front surface or the upper surface) of the second substrate 110, and a first channel structure CH1 extending in (e.g., penetrating) the gate stacking structure 120 and extending in a direction crossing the second substrate 110 (e.g., in a third direction Z perpendicular to the first surface of the second substrate 110) may be positioned. The cell insulating layers 132 and the gate electrodes 130 may be alternately stacked on the first surface of the second substrate 110.

In the cell array region 102, the horizontal conductive layers 112, and 114 may be positioned between the second substrate 110 and the gate stacking structure 120 (in the third direction Z). The horizontal conductive layers 112 and 114 may play a role in electrically connecting between the first channel structure CH1 and the second substrate 110.

For example, the horizontal conductive layers 112 and 114 may include a first horizontal conductive layer 112 positioned on the first surface (e.g., the upper surface) of the second substrate 110 and a second horizontal conductive layer 114 positioned on the first horizontal conductive layer 112.

As shown in FIG. 1, the first horizontal conductive layer 112 may be positioned between the second substrate 110 and the second horizontal conductive layer 114 (in the third direction Z).

In some region of the connection region 104, the first horizontal conductive layer 112 may not be positioned between the second substrate 110 and the gate stacking structure 120, but the horizontal insulating layer 116 may be positioned (between the second substrate 110 and the gate stacking structure 120). For example, in some region of the connection region 104, the horizontal insulating layer 116 may be positioned between the second substrate 110 and the second horizontal conductive layer 114 in the third direction Z.

As shown in FIG. 1, the horizontal insulating layer 116 may include (e.g., may be formed of) multiple layers including a plurality of insulating layers 116a, 116b, and 116c. However, the present disclosure is not limited thereto, and in some embodiments, the horizontal insulating layer 116 may be formed with a single layer, or an oxide layer may be further positioned above and/or below the horizontal insulating layer 116.

The first horizontal conductive layer 112 may function as a part of the common source line of the semiconductor device. For example, the first horizontal conductive layer 112 may function as a common source line together with the second substrate 110. As shown in FIG. 2, the first channel structure CH1 is extended to penetrate the horizontal conductive layers 112 and 114, reaching the second substrate 110, and the first gate dielectric layer 146 in the portion where the first horizontal conductive layer 112 is positioned may be removed so that the first horizontal conductive layer 112 may be directly connected (e.g., electrically connected) to the first channel layer 140 around the first channel layer 140. For example, the first channel structure CH1 may extend into at least a portion of the second substrate 110 and include the first gate dielectric layer 146 and the first channel layer 140. A portion of the first gate dielectric layer 146 overlapped with the first horizontal conductive layer 112 (and/or the second horizontal conductive layer 114) in a first direction X may be removed to expose the first channel layer 140 so that the first horizontal conductive layer 112 is in contact with the first channel layer 140. The first direction X may be parallel with (the upper surface and/or the lower surface of) the second substrate 110. As used herein, “an element A overlapping an element B in a direction X” (or similar language) means that there is at least one line that extends in the direction X and intersects both the elements A and B. Therefore, the first horizontal conductive layer 112 may electrically connect the second substrate 110 to the first channel layer 140.

The first and second horizontal conductive layers 112 and 114 may include a semiconductor material (e.g., polysilicon). For example, the first horizontal conductive layer 112 may include polysilicon doped with impurities, and the second horizontal conductive layer 114 may include polysilicon doped with impurities or may be a layer including impurities diffused from the first horizontal conductive layer 112. However, the present disclosure is not limited thereto, and the second horizontal conductive layer 114 may include an insulating material. In addition, in some embodiments, the second horizontal conductive layer 114 may be omitted.

On the first and second horizontal conductive layers 112 and 114 positioned on the second substrate 110, a gate stacking structure 120 where a cell insulating layer 132 and a gate electrode 130 are stacked may be positioned. The cell insulating layers 132 and the gate electrodes 130 may be alternately stacked.

In an embodiment, the gate stacking structure 120 may include a plurality of gate stacking structures 120a, 120b, and 120c sequentially stacked on the second substrate 110. Accordingly, it is possible to increase the total number of gate electrodes 130 to be stacked, thereby increasing the number of memory cells. As an example, when the gate stacking structure 120 includes the first, second, and third gate stacking structures 120a, 120b, and 120c, the structure may be simplified while increasing data storage capacity. However, the number of gate stacking structures 120 to be stacked is not limited thereto, and the gate stacking structure 120 may include two or less, or four or more gate stacking structures.

The gate electrode 130 of the gate stacking structure 120 may include a lower gate electrode 130L, a memory cell gate electrode 130M, and an upper gate electrode 130U sequentially positioned from the upper surface of the second substrate 110.

The lower gate electrode 130L may be used as a gate electrode of a ground selection transistor, the memory cell gate electrode 130M may constitute a memory cell, a part of the upper gate electrode 130U may be used as a gate electrode of a string selection transistor, and the remaining part may be used as a gate electrode of an erase transistor, which is employed in erasing operations utilizing the gate induced drain leakage (GIDL) phenomenon.

According to the data storage capacity of the semiconductor device, the number of memory cell gate electrodes 130M may be determined. According to some embodiments, each of the lower gate electrodes 130L and the upper gate electrodes 130U may be provided with one or more and may have the same structure either identical to or different from that of the memory cell gate electrode 130M. In addition, some of the gate electrodes 130, for example, some of the upper gate electrodes 130U, may be used as a gate electrode of a string selection transistor, and the remaining part may be used as the gate electrode for the erase transistor, which is employed in erasing operations utilizing the gate induced drain leakage (GIDL) phenomenon.

The cell insulating layer 132 may include an interlayer insulating layer 132m positioned between two adjacent gate electrodes 130 and/or under the gate electrode 130, and gate upper insulating layers 132a, 132b, and 132c respectively positioned above the first, second, and third gate stacking structures 120a, 120b, and 120c.

The first gate upper insulating layer 132a may be positioned between the first gate stacking structure 120a and the second gate stacking structure 120b (in the third direction Z), and the second gate upper insulating layer 132b may be positioned between the second gate stacking structure 120b and the third gate stacking structure 120c (in the third direction Z). The third gate upper insulating layer 132c may be an uppermost insulating layer positioned at an uppermost portion of the gate stacking structure 120. For example, the third gate upper insulating layer 132c may be on the third gate stacking structure 120c. The third gate upper insulating layer 132c may constitute a part or the entirety of the cell region insulating layer that is positioned over the entire upper part of the cell region 100.

In some embodiments, the thickness of the plurality of cell insulating layers 132 may not all be the same. For example, the thickness of gate upper insulating layers 132a, 132b, and 132c (in the third direction Z) may be thicker than that of interlayer insulating layer 132m. However, the shape, structure, and arrangement shape of the cell insulating layer 132 are not limited thereto, and may be variously changed.

Referring to FIG. 1, a connection region insulating layer 133 may be positioned in the connection region 104. As will be described in detail later, the connection region insulating layer 133 may be doped with impurities such as phosphorus, nitrogen, iron, and/or boron, but is not limited thereto. For example, the connection region insulating layer 133 may include silicon oxide doped with one or more of phosphorus, nitrogen, iron, and boron. In addition, the second connection insulating layer 137 may be positioned in the connection region 104 in which the source contact part 186 and the through contact part 188 are positioned. The connection region insulating layer 133 and the second connection region insulating layer 137 may include the same material or may include different materials.

The gate electrode 130 may include a conductive material. For example, the gate electrode 130 may include metal material such as tungsten (W), copper (Cu), and aluminum (Al), polycrystalline silicon, metal nitride (e.g., titanium nitride (TiN), tantalum nitride (TaN)), and/or a combination thereof. On the outside of the gate electrode 130, an insulating layer composed of an insulating material may be positioned, or a part of the first gate dielectric layer 146 may be positioned. For example, the gate electrode 130 may be in contact with an the insulating layer and/or the part of the first gate dielectric layer 146.

The cell insulating layer 132 may include an insulating material. For example, the cell insulating layer 132 may include silicon oxide, silicon nitride, silicon nitride oxide, a low dielectric constant material with a dielectric constant less than that of silicon oxide, and/or a combination thereof.

In the cell array region 102, the first channel structure CH1 may extend in a direction (e.g., a third direction Z perpendicular to the second substrate 110) crossing the second substrate 110 by passing through (e.g., penetrating) the gate stacking structure 120.

Referring to FIGS. 1 and FIG. 2, the first channel structure CH1 may include a first channel layer 140, and a first gate dielectric layer 146 positioned between the gate electrode 130 and the first channel layer 140 (in the first direction X and/or a second direction Y). The second direction Y may be parallel with the upper surface and/or the lower surface of the second substrate 110 and intersect with the first direction X.

The first channel structure CH1 may further include a first core insulating layer 142 positioned inside the first channel layer 140, and may further include a first channel pad 144 disposed on the first channel layer 140, the first core insulating layer 142, and/or the first gate dielectric layer 146. For example, in a cross-sectional view, the first channel layer 140 may extend around the first core insulating layer 142. The first channel layer 140 may be on a lower surface and side surfaces of the first core insulating layer 142.

Each of the first channel structures CH1 may form one memory cell string, and a plurality of first channel structures CH1 may be disposed to be spaced apart from each other while forming rows and columns in a plane. For example, a plurality of first channel structures CH1 may be arranged in various shapes such as a lattice shape, a zigzag shape, and the like in a plane. The first channel structure CH1 may have a column shape. For example, the first channel structure CH1 may have an inclined side surface so that the width becomes narrower as it approaches the second substrate 110 depending on the aspect ratio in a cross-section. However, it is not limited thereto, and the arrangement, structure, and shape of the first channel structure CH1 may be variously changed.

A first core insulating layer 142 may be positioned in the center portion of the first channel structure CH1, and the first channel layer 140 may extend around (e.g., surround) a side surface of the first core insulating layer 142. For example, the first core insulating layer 142 may have a column shape (e.g., a cylindrical shape or a polygonal column shape), and the first channel layer 140 may have a planar shape such as an annular shape. However, it is not limited thereto, and the first core insulating layer 142 may be omitted, and the first channel layer 140 may have a column shape (e.g., a cylindrical shape or a polygonal column shape).

The first channel layer 140 may include a semiconductor material, for example, polysilicon. The first core insulating layer 142 may include a insulating material. For example, the first core insulating layer 142 may include silicon oxide, silicon nitride, silicon nitride oxide, and/or a combination thereof. However, the materials of the first channel layer 140 and the first core insulating layer 142 are not limited thereto and may be variously changed.

The first gate dielectric layer 146 positioned between the gate electrode 130 and the first channel layer 140 may include a tunneling layer 146a, a charge storage layer 146b, and a blocking layer 146c sequentially stacked on the first channel layer 140.

The tunneling layer 146a may be a layer in which charge is tunneled according to voltage applied to the gate electrode 130 and may include an insulating material capable of tunneling charge. The tunneling layer 146a may include a material such as silicon oxide and/or silicon nitride oxide. For example, the tunneling layer 146a may be formed by stacking a layer including silicon oxide and a layer including silicon nitride.

The charge storage layer 146b positioned between the tunneling layer 146a and the blocking layer 146c (in the first direction X and/or the second direction Y) may be used as a data storage region. For example, the charge storage layer 146b may include silicon nitride capable of charge trapping. When the charge storage layer 146b is composed of silicon nitride, it may have excellent retention and be advantageous for integration compared to being composed of polysilicon. However, the material of the charge storage layer 146b is not limited thereto, and may be variously changed. The blocking layer 146c may be positioned between the charge storage layer 146b and the gate electrode 130 (in the first direction X and/or the second direction Y). The blocking layer 146c may include an insulating material to prevent an unwanted charge from flowing into the gate electrode 130. For example, the blocking layer 146c may include silicon oxide, silicon nitride, silicon nitride oxide, a high dielectric constant material, and/or a combination thereof.

The high dielectric constant material may mean a dielectric material having a higher dielectric constant than silicon oxide.

For example, the high dielectric constant material may include aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃), and/or a combination thereof.

The first channel pad 144 may be positioned on the first channel layer 140, the first core insulating layer 142, and/or the first gate dielectric layer 146. The first channel pad 144 may overlap in the third direction Z with (e.g., cover) an upper surface of the first core insulating layer 142 and may be positioned to be electrically connected to the first channel layer 140. In FIG. 1 and FIG. 2, the first channel pad 144 is shown to overlap in the third direction Z with (e.g., cover) the upper surface of the first gate dielectric layer 146 but is not limited. For example, the first channel pad 144 may not cover the upper surface of the first gate dielectric layer 146. That is, the side surface of the first channel pad 144 may be surrounded by the first gate dielectric layer 146. For example, the first gate dielectric layer 146 may be on (may extend around) the side surface of the first channel pad 144. A side surface of the first channel pad 144 may be in contact with the tunneling layer 146a. The first channel pad 144 may include a conductive material, for example, a polysilicon doped with impurity. However, the material of the first channel pad 144 is not limited thereto and may be variously changed.

As described above, when the gate stacking structure 120 includes a plurality of gate stacking structures 120a, 120b, and 120c stacked with each other, the first channel structure CH1 may include a plurality of sub-channel structures CH1a, CH1b, and CH1c extending in (e.g., passing through) the plurality of gate stacking structures 120a, 120b, and 120c (in the third direction Z), respectively. For example, when the gate stacking structure 120 includes a first gate stacking structure 120a, a second gate stacking structure 120b, and a third gate stacking structure 120c, the first channel structure CH1 may include a first sub-channel structure CH1a extending in (through) the first gate stacking structure 120a (in the third direction Z), a second sub-channel structure CH1b extending in (through) the second gate stacking structure 120b (in the third direction Z), and a third sub-channel structure CH1c extending in (through) the third gate stacking structure 120c (in the third direction Z).

The first, second, and third sub-channel structures CH1a, CH1b, and CH1c may be connected (e.g., electrically connected) to each other. Each of the first, second, and third sub-channel structures CH1a, CH1b, and CH1c may have an inclined side surface so that the width (in the first direction X and/or the second direction Y) becomes narrower as it approaches the second substrate 110 according to the aspect ratio in a cross-section. As shown in FIG. 2, a part where the first sub-channel structure CH1a and the second sub-channel structure CH1b are connected, and a part where the second sub-channel structure CH1b and the third sub-channel structure CH1c are connected may include a bent part due to a difference in width (in the first direction X and/or the second direction Y). However, a connection form of the first, second, and third sub-channel structures CH1a, CH1b, and CH1c is not limited thereto, and may be variously changed. For example, in some embodiments, the first, second, and third sub-channel structures CH1a, CH1b, and CH1c may have an inclined side surface continuously connected without a bent part therebetween.

FIG. 2 illustrates that the first gate dielectric layer 146, the first channel layer 140, and the first core insulating layer 142 of each of the first, second, and third sub-channel structures CH1a, CH1b, and CH1c may have an integral structure formed by extending each other. After forming a first, second, and third sub-channel holes for the first, second, and third sub-channel structures CH1a, CH1b, and CH1c, the structure described above may be formed by forming the first gate dielectric layer 146, the first channel layer 140, and the first core insulating layer 142 over the entire first, second, and third sub-channel holes. Herein, an integral structure may refer to a structure that has no visually (or chemically) distinguishable sub-elements and is manufactured by the same process or series of processes. However, it is not limited thereto. For example, the first, second, and third sub-channel structures CH1a, CH1b, and CH1c may have their first gate dielectric layer 146, first channel layer 140, and first core insulating layer 142 formed independently, allowing them to be (electrically) connected each other. That is, after forming a first sub-channel hole for the first sub-channel structure CH1a, (a portion of) the first gate dielectric layer 146, (a portion of) the first channel layer 140, and (a portion of) the first core insulating layer 142 are formed in the first sub-channel hole, after forming a second sub-channel hole for the second sub-channel structure CH1b, (a portion of) the first gate dielectric layer 146, (a portion of) the first channel layer 140, and (a portion of) the first core insulating layer 142 are formed in the second sub-channel hole, and after forming a third sub-channel hole for the third sub-channel structure CH1c, (a portion of) the first gate dielectric layer 146, (a portion of) the first channel layer 140, and (a portion of) the first core insulating layer 142 are formed in the third sub-channel hole.

In some embodiments, among the plurality of gate stacking structures 120, the first channel pad 144 may be provided on the first channel structure CH1, for example, the third sub-channel structure CH1c which may extend in (e.g., pass through) the upper positioned gate stacking structure 120, for example, the third gate stacking structure 120c. However, it is not limited thereto, and in some embodiments, the first channel pad 144 may be positioned above the first sub-channel structure CH1a, the second sub-channel structure CH1b, and the third sub-channel structure CH1c, respectively. Accordingly, the first channel pad 144 of the first sub-channel structure CH1a or the second sub-channel structure CH1b may be connected (e.g., electrically connected) to the first channel layer 140 of the second sub-channel structure CH1b or the third sub-channel structures CH1c positioned thereon.

In some embodiments, the gate stacking structure 120 may extend in an intersection direction (e.g., the third direction Z, which is a vertical direction) crossing the second substrate 110 and may be divided into a plurality of sections in a plane. That is, the gate stacking structure 120 may be divided into a plurality of sections in a plane by the separation structure 136 extending in (e.g., passing through) the gate stacking structure 120.

Referring to FIG. 1, the separation structure 136 may extend (in the third direction Z) to the second substrate 110 by passing through the gate electrode 130 and the cell insulating layer 132. A separation structures 136 may extend in the second direction Y in a plane and may be provided to be spaced apart from each other at a predetermined interval in the first direction X.

Accordingly, each of the plurality of gate stacking structures 120 may extend in the second direction Y in a plane, and may be spaced apart from each other at a predetermined interval in the first direction X.

The gate stacking structure 120 partitioned by the separation structure 136 may constitute one memory cell block. However, the present disclosure is not limited thereto, and the range of the memory cell block is not limited thereto.

The separation structure 136 may have an inclined side surface where the width (in the first direction X) is decreased as it approaches the second substrate 110 in a cross section due to a high aspect ratio. However, the cross-sectional shape of the separation structure 136 is not limited thereto, and the side surface of the separation structure 136 may be perpendicular to the second substrate 110.

Although FIG. 1 illustrates that the separation structure 136 in a cross section includes a continuously inclined side surface in the first, second, and third gate stacking structures 120a, 120b, and 120c and does not include a bent part, but the separation structure 136 is not limited thereto and may include a bent part at a boundary between the first gate stacking structure 120a and the second gate stacking structure 120b as well as between the second gate stacking structure 120b and the third gate stacking structure 120c.

The separation structure 136 may be (at least partially) filled with an insulating material. For example, the separation structure 136 may include an insulating material such as silicon oxide, silicon nitride, and/or silicon nitride oxide. However, it is not limited thereto, and a structure, a shape, a material, etc. of the separation structure 136 may be variously changed.

In the connection region 104, a gate electrode 130, horizontal conductive layers 112, 114, a second substrate 110, and/or components for connection with the circuit region 200 may be positioned. In addition, the connection region 104 may include an input/output pad and a portion where the input/output connection wire is positioned.

Specifically, a plurality of gate electrodes 130 may extend from the cell array region 102 toward the connection region 104 in the second direction Y. In the connection region 104, the extension length of the plurality of gate electrodes 130 in the second direction Y may sequentially (and discretely) decrease as they move away from the second substrate 110. For example, a plurality of gate electrodes 130 may be positioned in the connection region 104 with a stepped shape (in a cross-sectional view).

The plurality of gate electrodes 130 may have a step shape in one direction or a plurality of directions. Accordingly, a plurality of gate electrodes 130 stacked in the vertical direction (e.g., in the third direction Z) in the connection region 104 may be sequentially connected (e.g., electrically connected) to the gate contact part 184.

In FIG. 1, the gate electrode 130 located in the second gate stacking structure 120b has a step shape (in a cross-sectional view), but the gate electrode 130 positioned in the first gate stacking structure 120a and/or the third gate stacking structure 120c in other regions may also have a step shape (in a cross-sectional view).

The gate contact part 184 may extend in (e.g., pass through) the gate stacking structure 120 in the connection region 104 (in the third direction Z) to be connected (e.g., electrically connected) to the gate electrode 130, and may extend to the third lower wire layer 256 of the circuit region 200 to be electrically connected to the circuit region 200. A plurality of gate contact parts 184 may be provided to be spaced apart from each other at a predetermined interval in the first direction X (and/or in the second direction Y).

Specifically, a plurality of gate contact parts 184 may (sequentially) extend in (e.g., pass through) the insulating layers (e.g., the cell region insulating layer that is positioned over the entire upper part of the cell region 100), the gate stacking structures 120, the horizontal conductive layers 112 and 114, the second substrate 110, and the third circuit insulating layer 236 of the cell region 100 (in the third direction Z) to be electrically connected to the circuit region 200.

Referring to FIGS. 1 and FIG. 4, in the cell array region 102, the plurality of gate electrodes 130 may include a connection gate electrode 130c having a pad part WP and a stack gate electrode 130r positioned under (below) the connection gate electrode 130c. In some embodiments, the stack gate electrode 130r may be positioned on (over) another connection gate electrode 130c. For example, the stack gate electrodes 130r may be between the connection gate electrodes 130c in the third direction Z. As shown in FIG. 4, edges of the connection gate electrode 130c and the stack gate electrode 130r may coincide with each other (e.g., aligned with each other in the third direction Z). As described above, one connection gate electrode 130c and one or more stack gate electrodes 130r having matching (e.g., aligned) edges may form a step structure 139. In this case, the number of stack gate electrodes 130r forming the step structure 139 is not limited to the number shown in FIG. 4.

As illustrated in FIG. 3 and FIG. 4, the thickness of the connection gate electrode 130c (in the third direction Z) may be thicker than that of the stack gate electrode 130r on the upper surface of the step structure 139. For example, the uppermost stack gate electrode 130r of the step structure 139 may have a less (thinner) thickness in the third direction Z that of the connection gate electrode 130c of the step structure 139 on the uppermost stack gate electrode 130r of the step structure 139. However, this is an example, and the present disclosure is not limited to this structure.

Referring to FIG. 3, the gate contact part 184 may be electrically connected to the connection gate electrode 130c having the pad part WP among the plurality of gate electrodes 130 included in the gate stacking structure 120, and may be spaced apart (e.g., electrically insulated) from the stack gate electrode 130r with the gate insulating pattern 184p interposed therebetween.

The pad part WP of the connection gate electrode 130c may be positioned at an end part of the connection gate electrode 130c far from the cell array region 102. For example, the pad part WP may be the farther portion of the connection gate electrode 130c from the cell array region 102 (in the first direction X and/or the second direction Y). The gate contact part 184 may be connected to the inner side surface of the pad part WP (of the connection gate electrode 130c) while extending in (e.g., passing through) the pad part WP of the connection gate electrode 130c. As shown in FIG. 3, the gate contact part 184 may include a connection part that protrudes (in the first direction X and/or the second direction Y) toward the inner side surface of the pad part WP (of the connection gate electrode 130c) and directly contacts the pad part WP.

The gate contact part 184 may include a conductive material, for example, tungsten W, copper Cu, aluminum Al, and/or the like, and may further include a diffusion barrier layer. However, it is not limited to the material of the gate contact part 184 and may be variously changed.

The gate insulating pattern 184p may be positioned between the stack gate electrode 130r and the gate contact part 184 (in the first direction X and/or in the second direction Y) except for the connection gate electrode 130c. The gate contact part 184 and the stack gate electrode 130r may be electrically insulated from each other by the gate insulating pattern 184p.

The gate insulating pattern 184p may include an insulating materials such as silicon oxide, silicon nitride, and/or silicon nitride oxide, but is not limited thereto.

The gate contact part 184 may have an inclined side surface in cross section so that the width (in the first direction X and/or in the second direction Y) becomes narrower as it approaches the second substrate 110 according to the aspect ratio and may include a bent part at the boundary of the plurality of gate stacking structures 120a, 120b, and 120c. However, the shape of the cross section of the gate contact part 184 is not limited thereto and may be variously changed. For example, the gate contact part 184 may not include a bent part at the boundary of the plurality of gate stacking structures 120a, 120b, and 120c.

The source contact part 186 and the through contact part 188 may be positioned outside the gate stacking structure 120 in the connection region 104. In the connection region 104, the through contact part 188 may extend in (e.g., sequentially pass through) the insulating layers (e.g., the cell region insulating layer that is positioned over the entire upper part of the cell region 100), the second substrate 110, and the third circuit insulating layer 236 of the cell region 100, and may extend to the third lower wire layer 256 of the circuit region 200 to be electrically connected to the circuit region 200.

Although FIG. 1 illustrates a configuration in which the source contact part 186 is directly connected to the second substrate 110, the connection relationship between the source contact part 186 and the second substrate 110 is not limited thereto and may be variously changed. For example, as the source contact part 186 may be connected to the third lower wire layer 256 and the second substrate 110 may be connected to the third lower wire layer 256 through a contact hole 236H, the source contact part 186 and the second substrate 110 may be electrically connected through the third lower wire layer 256.

In FIG. 1, the source contact part 186 and/or the through contact part 188 may have an inclined side surface in a cross-sectional view so that the width (in the first direction X and/or the second direction Y) decreases as it approaches the second substrate 110 according to the aspect ratio and may include a bent part at the boundary of the plurality of gate stacking structures 120a, 120b, and 120c. However, the shape of the source contact part 186 and the through contact part 188 in the cross section is not limited thereto and may be variously changed. For example, the source contact part 186 and/or the through contact part 188 may not include a bent part at the boundary of the plurality of gate stacking structures 120a, 120b, and 120c.

The source contact part 186 and the through contact part 188 may include a conductive material, such as tungsten W, copper Cu, aluminum Al, etc. However, it is not limited thereto, and the material included in the source contact part 186 and the through contact part 188 may be variously changed.

In some embodiments, each of the gate contact part 184, the source contact part 186, and the through contact part 188 may include a gate barrier pattern (not shown) extending around (e.g., surrounding) (a side surface and a lower surface of each of) the gate contact part 184, the source contact part 186, and the through contact part 188. The gate barrier pattern may be on (e.g., cover) side surfaces and lower surfaces of the gate contact part 184, the source contact part 186, and the through contact part 188. However, the arrangement relationship between the gate barrier pattern and the gate contact part 184, the source contact part 186, and the through contact part 188 is not limited thereto and may be variously changed. For example, the gate barrier pattern may be on (e.g., cover) the side surfaces other than the bottom surface of the gate contact part 184, the source contact part 186, and the through contact part 188.

The gate barrier pattern may include, for example, a metal layer and/or a metal nitride layer. The metal layer may include, for example, titanium, tantalum, tungsten, nickel, cobalt, and/or platinum. The metal nitride layer may include, for example, a titanium nitride layer TiN, a tantalum nitride layer TaN, a tungsten nitride layer WN, a nickel nitride layer NiN, a cobalt nitride layer CoN, and/or a platinum nitride layer PtN.

Referring to FIG. 1, a bit line 182 and a connection wire 191 may be positioned on the cell insulating layer 132. The bit line 182 may be positioned on the cell insulating layer 132 of the gate stacking structure 120 formed in the cell array region 102. The bit line 182 may extend in an intersecting direction (in the first direction X of the drawing) intersecting one direction in which the gate electrode 130 extends. The bit line 182 may be electrically connected to the first channel structure CH1, for example, the channel pad 144, through a contact via 180a.

The connection wire 191 may be positioned in the cell array region 102 and/or the connection region 104. The bit line 182, the source contact part 186, and/or the through contact part 188 may be electrically connected to the connection wire 191. For example, the source contact part 186 and/or the through contact part 188 may be connected to the connection wire 191 through a contact via 180a. However, depending on the embodiment, the degree of design freedom may be improved without including the contact via 180a and the connection wire 191 connected to the gate contact part 184. For example, the gate contact part 184 may not be in direct contact with the contact via 180a or the connection wire 191.

In FIG. 1, the connection wire 191 is provided as a single layer positioned on the same plane as the bit line 182, and the wire insulating layer 192 is positioned in other parts. For example, the wire insulating layer 192 may be positioned on the same plane as the bit line 182, and the connection wire 191 may be in the wire insulating layer 192. However, this is only a brief illustration for convenience. Therefore, the connection wire 191 may include a plurality of wire layers and further include a contact via for electrical connection with the bit line 182, the gate contact part 184, the source contact part 186, and/or the through contact part 188.

In this way, the bit line 182, the gate electrode 130, the horizontal conductive layers 112 and 114, and/or the second substrate 110 connected to the first channel structure CH1 may be electrically connected to the circuit element 220 of the circuit region 200.

Referring to FIG. 1, a connection region insulating layer 133 is positioned in the connection region 104. As described above, the edges of the connection gate electrode 130c and one or more stack gate electrodes 130r may coincide (e.g., may be aligned with each other (in the second direction Y)) in the connection region 104, and in this manner, one connection gate electrode 130c and one or more stack gate electrodes 130r having matching edges (aligned edges) may form a step structure 139. The number of stack gate electrodes 130r forming one step structure 139 is not limited to the number shown in FIG. 1 and FIG. 4 and may be various.

The connection region insulating layer 133 may include, for example, silicon oxide. For example, the connection region insulating layer 133 may include doped silicon oxide. The connection region insulating layer 133 may be doped with, for example, one or more of phosphorus, nitrogen, iron, and boron. For example, the connection region insulating layer 133 may include phosphorus or nitrogen-doped silicon oxide.

In this way of doping, the etching rate of the connection region 104 and the etching rate of the cell array region 102 may be similarly adjusted. In the manufacturing process, a process of forming a hole to form the first channel structure CH1 of the cell array region 102 may be needed, and a process of forming a hole to form contact parts 184, 186, and 188 in the connection region 104 may be needed. In this case, a process of forming a hole in the cell array region 102 and a process of forming a hole in the connection region 104 may be separately performed. Since the stacking structure of the cell array region 102 and the stacking structure of the connection region 104 are different, the etching rate of each region may not be the same, therefore, it can be challenging to form holes in each region (the cell array region 102 and the connection region 104) at the same time in a single process.

However, when doping the connection region insulating layer 133, the time required to form a hole in the connection region insulating layer 133 and the time required to form a hole in the cell array region 102 may be similarly (or equally) adjusted. Specifically, when phosphorus, nitrogen, iron, and/or boron is doped into the connection region insulating layer 133, the etching rate of the connection region 104 and the etching rate of the cell array region 102 may become similar (or identical). Accordingly, the hole of the cell array region 102 and the hole of the connection region 104 may be formed in one process, thereby simplifying the process.

The connection region insulating layer 133 may be formed by plasma chemical vapor deposition (PECVD). In this case, the connection region insulating layer 133 may not be uniformly formed due to the straightness characteristic of the plasma.

The present embodiment may be characterized in that an auxiliary layer 134 is formed between the connection region insulating layer 133 and the gate electrode 130 in order to uniformly form the connection region insulating layer 133.

Referring to FIG. 1 and FIG. 4, an auxiliary layer 134 may be positioned between the connection region insulating layer 133 and the step structure 139 of the gate electrode 130.

The auxiliary layer 134 may include a different material from that of the connection region insulating layer 133. As an example, the auxiliary layer 134 may include a flowable material. The flowable material may mean a material having flowability during heat treatment after deposition. For example, when heat is applied after depositing a material in a vertical corner, as the angle of the corner part changes due to its flowable characteristic, the angle becomes smooth. The auxiliary layer 134 may be a material including, for example, boron, phosphorus, nitrogen, iron, and/or a combination thereof. The auxiliary layer 134 may include a material different from that of the connection region insulating layer 133, and the connection region insulating layer 133 may include, for example, silicon oxide doped with phosphorus, nitrogen, iron, and/or boron. The auxiliary layer 134 may include a material including, for example, boron, phosphorus, nitrogen, iron, and/or a combination thereof, and in this case, the content of boron, phosphorus, nitrogen, iron, and/or a combination thereof included in the auxiliary layer 134 may be greater than the content of phosphorus, nitrogen, iron, and/or boron doped in the connection region insulating layer 133. For example, the auxiliary layer 134 and the connection region insulating layer 133 may include a same dopant material with different concentrations.

For example, the auxiliary layer 134 may include borophosphosilicate glass BPSG, phosphosilicate glass PSG, borosilicate glass BSG, tonen silazene TOSZ, octamethylcyclotetrasiloxane OMCTS, flowable oxide FOx, arsenosilicates AsSG and/or a combination thereof. However, it is not limited to the materials illustrated above, and any material (e.g., any material compatible with other processes) that has flowability and a gentle angle through heat treatment after deposition may be used. A glass transition temperature of the auxiliary layer 134 may be lower than a glass transition temperature of the connection region insulating layer 133. Therefore, through the heat treatment, the auxiliary layer 134 may have flowability and may have a gentle angle (while the connection region insulating layer 133 remains without flowability).

Referring to FIG. 1 and FIG. 4, the auxiliary layer 134 may be formed to be curved at the corner of the step structure 139. This is, as described above, because the auxiliary layer 134 is formed of a flowable material and has a curved surface by heat treatment after deposition.

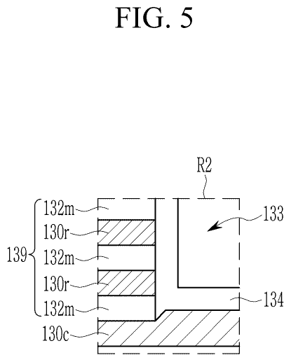

FIGS. 5 to 7 are schematic diagrams briefly illustrating the forming process of an auxiliary layer 134 having a curved surface according to some embodiments.

Referring to FIG. 5, an auxiliary layer 134 may be formed on the front surface of the step structure 139. At this time, the auxiliary layer 134 may be formed on (along) the side surface of the step structure 139 and may be formed at a certain angle at the corner of the step structure 139. For example, the auxiliary layer 134 may be on at least some of the side surfaces of the stack gate electrodes 130r in a first step structure 139, and an upper surface of a connection gate electrode 130c of a second step structure 139. The first step structure 139 may be on the second step structure 139.

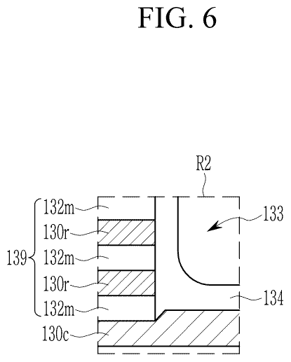

Next, referring to FIG. 6, the auxiliary layer 134 may be reflowed by applying heat to the auxiliary layer 134. In this process, the angle of the auxiliary layer 134 may be gentle in the corner part (between the first and second step structures 139). That is, in FIG. 5, the auxiliary layer 134 is formed to have a corner, but through the reflow process of FIG. 6, the corner of the auxiliary layer 134 may be formed to have a gentle curved surface.

The heat treatment temperature in this step may vary depending on the material in the auxiliary layer 134. The edge of the auxiliary layer 134 may be performed (treated) at a temperature such that the corner becomes curved, and the heat treatment time may be, for example, (about) 20 minutes to (about) 3 hours.

The heat treatment temperature may vary depending on the material in the auxiliary layer 134. For example, when the auxiliary layer 134 includes a flowable oxide FOx, the heat treatment temperature may be, for example, (about) 200° C. to (about) 250° C. The flowable oxide FOx may be a material in which some of the conventional silicate-based Si—O—Si bonds are replaced by Si—H bonds to substitute one H for each Si and may inhibit the densification of the bonding network, resulting in a material with low density.

In addition, when the auxiliary layer 134 includes a phosphosilicate glass PSG, the heat treatment temperature may be, for example, (about) 1000° C. to (about) 1100° C. When the auxiliary layer includes a borophosphosilicate glass BPSG, the heat treatment temperature may be, for example, (about) 800° C. to (about) 950° C.

When the auxiliary layer 134 includes boron B, the heat treatment temperature may vary depending on the concentration of boron. For example, when the concentration of boron in the auxiliary layer increases by 1 wt %, the heat treatment temperature may decrease by (about) 40° C. However, if the boron concentration increases by 5 wt % or more, for example, an additional decrease in heat treatment temperature may not occur.

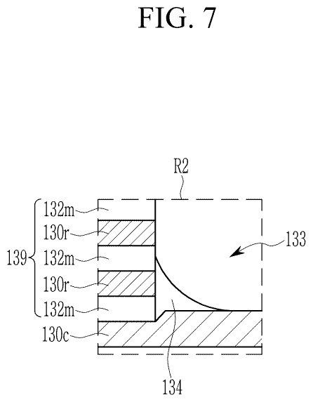

Next, referring to FIG. 7, the auxiliary layer 134 may be partially removed through etching. At this time, the etching may be performed by isotropic etching, and in this process, some of the auxiliary layers 134 positioned at the corner of the step structure 139 may remain. Since the auxiliary layer 134 is formed to have a gentle corner in the previous reflow process, the remaining auxiliary layer 134 may also have a gentle corner, that is, a curved surface. In this case, the auxiliary layer 134 may be formed as a concave curved surface with respect to the corner of the step structure 139. For example, the auxiliary layer 134 may be concave toward the corner of the step structure 139.

Referring back to FIG. 4, the width D2 (in the second direction Y) of the auxiliary layer 134 positioned on the upper surface of the step structure 139 (e.g., the second step structure 139) may be, for example, (about) 20 nm to (about) 120 nm. In addition, the height D1 of the auxiliary layer 134 (in the third direction Z) positioned on the side surface of the step structure 139 may be greater than (about) 20 nm. The maximum height of the auxiliary layer 134 is not limited but may be formed lower than the height of the step structure 139 (e.g., the first step structure 139). For example, the height D1 of the auxiliary layer 134 may be (about) 20 to (about) 120 nm. However, this is an example, and the present disclosure is not limited thereto.

As shown in FIG. 1 and FIG. 4, the auxiliary layer 134 may be formed at the corner of the step structure 139 and may be formed in a curved surface. Accordingly, the angle formed by the corner of the step structure 139 may be alleviated. When the auxiliary layer 134 is not formed, the corner of the step structure 139 is close to a right angle, but a gentle angle (e.g., a more gentle angle than the right angle) may be formed by forming the auxiliary layer 134.

This auxiliary layer 134 may solve the problem that the connection region insulating layer 133 is not uniformly formed in the process of forming the connection region insulating layer 133. The connection region insulating layer 133 may be formed by a plasma chemical vapor deposition (PECVD) method as described above, and in this case, the connection region insulating layer 133 may not be uniformly formed due to straightness characteristic of the plasma.

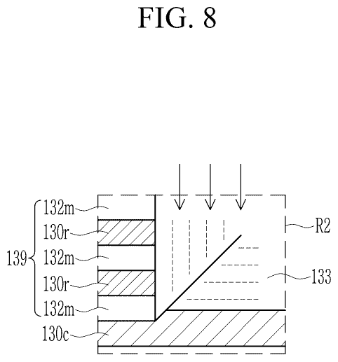

FIG. 8 is a schematic diagram illustrating the forming process of the connection region insulating layer 133 in case the auxiliary layer 134 is not formed. Referring to FIG. 8, the plasma of the connection region insulating layer 133 (e.g., the plasma of the formation process for the connection region insulating layer 133) may proceed in a straight direction. At this time, a first plane that is parallel with the substrate (e.g., the second substrate 110) may be directly subjected to the plasma, which means that the plasma moving direction for the connection region insulating 133 is perpendicular to the first plane, so that a first step insulating layer of the connection region insulating layer 133 may be uniformly formed on the first plane. On the other hand, when a second plane is perpendicular to the substrate (e.g., the second substrate 110), which means that the moving direction of the plasma for the connection region insulating 133 and the deposition surface (e.g., the second plane) are parallel with each other, a second step insulating layer of the connection region insulating layer 133 may be formed at a relatively lower density on the second plane. In FIG. 8, a deposition direction of the connection region insulating layer 133 formed in each region is shown by a dotted line. However, the deposition direction of the connection region insulating layer 133 is not limited to the illustration in FIG. 8. As shown in FIG. 8, the directions in which the connection region insulating layer 133 is formed on the front surface (e.g., the first plane or the upper surface of the connection gate electrode 130c below the step structure 139) and the side surface (e.g., the second plane or the side surface of the step structure 139) are different, and the interface between the different forming directions of the connection region insulating layer 133 may cause a boundary surface or an empty space as shown in FIG. 8. That is, a defect may occur at the interface between the connection region insulating layer 133 formed from the upper surface of the connection gate electrode 130c below the step structure 139 and the connection region insulating layer 133 formed from the side surface of the step structure 139. These defects may hinder the uniform formation of holes during the hole formation process for forming the gate contact part (e.g., the gate contact part 184). That is, if the connection region insulating layer 133 is not uniformly formed and a defect (empty space or boundary surface) is formed therein, it may cause a defect in a subsequent process.

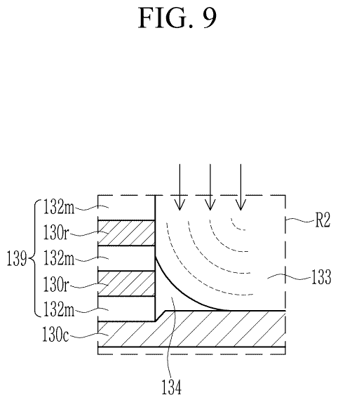

However, the semiconductor device according to the present embodiment may alleviate the angle of the corner of the step structure 139 by forming the auxiliary layer 134, thereby minimizing the occurrence of such defects. FIG. 9 illustrates a forming process of a connection region insulating layer 133 when an auxiliary layer 134 is included as in the present embodiment. In FIG. 9, a deposition direction of the connection region insulating layer 133 is shown by a dotted line. Referring to FIG. 9, when the auxiliary layer 134 is included, an angle of a corner of the step structure 139 becomes gentle (e.g., gentler than the right angle). Therefore, the angle between the connection region insulating layer 133 formed from the upper surface of the connection gate electrode 130c below the step structure 139 and the connection region insulating layer 133 formed from the side surface of the step structure 139 becomes smooth (e.g., smoother than the right angle), thereby reducing (e.g., minimizing) the occurrence of defects between the connection region insulating layer 133 formed from the upper surface of the connection gate electrode 130c below the step structure 139 and the connection region insulating layer 133 formed from the side surface of the step structure 139.

In FIG. 1, though a configuration in which an auxiliary layer 134 is formed on (the corner of) the step structure 139 of the second gate stacking structure 120b is illustrated, the first gate stacking structure 120a and the third gate stacking structure 120c also may include a step structure 139 and may include an auxiliary layer 134 positioned in contact with (the corner of) the step structure 139.

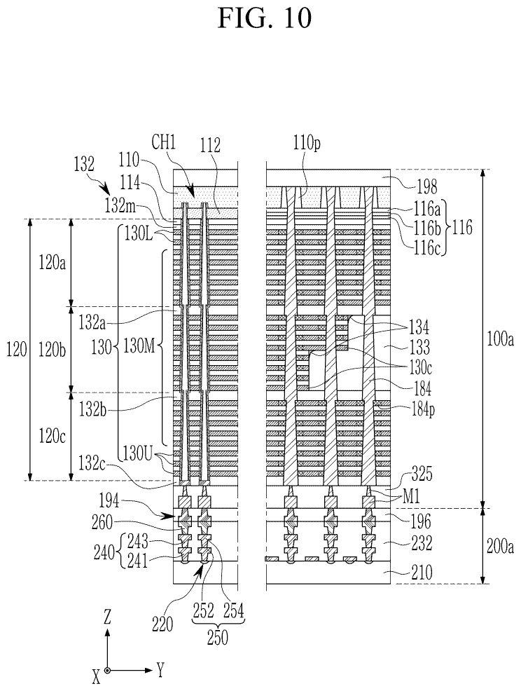

FIG. 10 is a cross-sectional view schematically illustrating a semiconductor device according to some embodiments.

The semiconductor device according to an embodiment illustrated in FIG. 10 may have a chip-to-chip (C2C) structure bonded by a wafer bonding method. That is, after manufacturing a lower chip including the circuit region 200a formed on the first substrate 210 and an upper chip including the cell region 100a formed on the second substrate 110, the semiconductor device according to the embodiment shown in FIG. 10 may be manufactured by bonding them.

The circuit region 200a may include the first substrate 210, the circuit element 220, the lower conductive via 240, the lower wire 250, and the lower wire 250, and may further include a first bonding structure 260 positioned on a surface facing the cell region 100a.

The cell region 100a may include the second substrate 110, the gate stacking structure 120, the first channel structure CH1, the gate contact part 184, and the first upper wire structure M1, and may further include a second bonding structure 194 positioned on a surface facing the circuit region 200a.

The second substrate 110 may be a semiconductor substrate including a semiconductor material. For example, the second substrate 110 may be a semiconductor substrate made of a semiconductor material, or a semiconductor substrate having a semiconductor layer formed on a base substrate. For example, the second substrate 110 may include a monocrystalline or polycrystalline silicon, germanium, silicon-germanium, silicon-on-insulator, and/or germanium-on-insulator.

In the gate stacking structure 120, the gate electrode 130 may include a lower gate electrode 130L, a memory cell gate electrode 130M, and an upper gate electrode 130U sequentially positioned on the second substrate 110 while the gate electrode 130 faces the circuit region 200a from the second substrate 110. That is, as shown in FIG. 10, as the gate stacking structure 120 may be sequentially stacked on the lower part of the second substrate 110 on the drawing, the gate stacking structure 120 shown in FIG. 1 may be arranged in a form that is vertically inverted (e.g., inverted in the third direction Z) and disposed.

A fourth upper insulating layer 325 may be stacked on the gate stacking structure 120. The fourth upper insulating layer 325 may include for example, silicon oxide, silicon nitride, and/or silicon nitride oxide. However, it is not limited thereto, and the material included in the fourth upper insulating layer 325 may be variously changed.

The first upper wire structure M1 may be positioned in the fourth upper insulating layer 325. The first upper wire structure M1 may include a conductive material such as tungsten (W), copper (Cu), and aluminum (Al) and may be electrically connected to the first channel structure CH1 and the gate contact part 184. The first upper wire structure M1 positioned on the gate stacking structure 120 may be positioned adjacent to the circuit region 200a. A region other than the second bonding structure 194 may be covered by the bonding insulating layer 196. For example, the second bonding structure 194 may be in the bonding insulating layer 196. A portion (e.g., a lower surface) of the second bonding structure 194 may be exposed from the bonding insulating layer 196. As described above, the second bonding structure 194 may be positioned to face the circuit region 200a in the cell region 100a.

For example, the second bonding structure 194 of the cell region 100a and the first bonding structure 260 of the circuit region 200a may include aluminum (Al), copper (Cu), tungsten (W), and/or an alloy including the same. For example, the first and second bonding structures 260 and 194 may include copper, so that the cell region 100a and the circuit region 200a may be connected (e.g., directly contact and bond) by copper-to-copper bonding.

In FIG. 10, the structure and connection relationship of the gate stacking structure 120, the gate contact part 184, the source contact part 186 (not shown), and the through contact part 188 (not shown) described above with reference to FIGS. 1 to FIG. 4 are similarly or identically applied. In addition, the descriptions of the connection region insulating layer 133 and the auxiliary layer 134 may be applied in a similar or the same manner. In addition, the description of the same structure described in FIGS. 1 to 4 is applied in a similar or the same way.

The semiconductor device according to the present embodiment may further include an input/output pad (not shown) and an input/output connection wire (not shown) electrically connected thereto. The input/output connection wire may be electrically connected to some of the second bonding structures 194. The input/output pad may be positioned, for example, on the insulating layer 198 on (overlapping in the third direction Z or covering) the outer surface (e.g., the upper surface) of the second substrate 110. In some embodiments, a separate input/output pad electrically connected to the circuit region 200a may be provided.

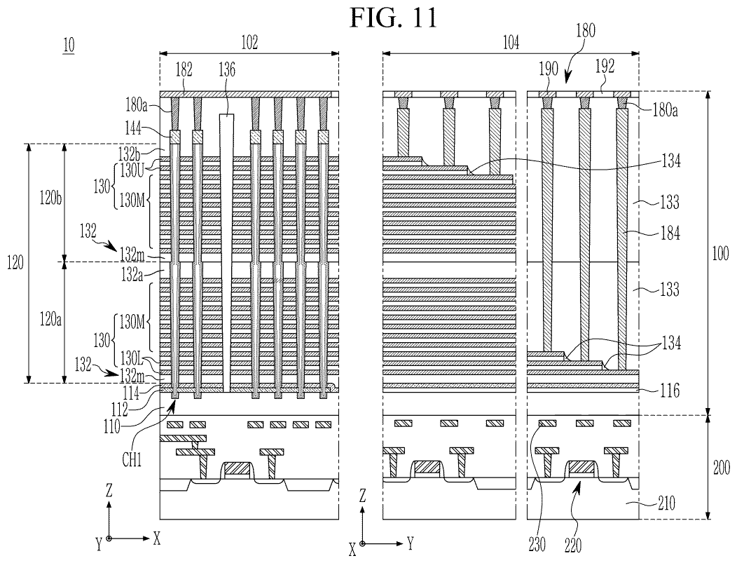

FIG. 11 is a cross-sectional view schematically illustrating a semiconductor device according to some embodiments. Referring to FIG. 11, the semiconductor device according to the present embodiment is the same (or similar) as the embodiment of FIG. 1 except for the shape of the gate contact part 184 and the shape of the gate electrode layer 130. A specific description of the same components may be omitted, and hereinafter, the difference from FIG. 1 will be mainly described. The embodiment of FIG. 11 is different from that of FIG. 1 in that the gate contact part 184 does not pass through the gate stacking structure 120. Referring to FIG. 11, a cell region 100 and a circuit region 200 in which a peripheral circuit structure for controlling an operation of the memory cell structure is provided may be included.

The circuit region 200 may include a peripheral circuit structure formed on the first substrate 210, and the cell region 100 may include a gate stacking structure 120 and a first channel structure CH1 positioned on (in) the cell array region 102 of the second substrate 110 as a memory cell structure. A first wire part 230 electrically connected to the peripheral circuit structure may be positioned in the circuit region 200, and a second wire part 180 electrically connected to the memory cell structure may be positioned in the cell region 100.

The circuit region 200 may include a first substrate 210, a circuit element 220, and a first wire part 230 positioned on the first substrate 210.

The first substrate 210 may be a semiconductor substrate including a semiconductor material. For example, the first substrate 210 may be a semiconductor substrate made of a semiconductor material, or a semiconductor substrate in which a semiconductor layer is formed on the base substrate. For example, the first substrate 210 may include (e.g., may be formed of) silicon, epitaxial silicon, germanium, silicon-germanium, silicon-on-insulator SOI, and/or germanium-on-insulator GOI.

The cell region 100 may include a cell array region 102 and a connection region 104. The gate stacking structure 120 and the first channel structure CH1 may be positioned on the second substrate 110 in the cell array region 102. A gate stacking structure 120 and/or a structure for connecting the first channel structure CH1 positioned in the cell array region 102 to the circuit region 200 or an external circuit may be positioned in the connection region 104.

In some embodiments, the second substrate 110 may include a semiconductor material. For example, the second substrate 110 may include polysilicon doped with impurity. The second substrate 110 may perform a function as a common source line. The second substrate 110 may function as a source region for supplying a current to the memory cells positioned on the second substrate 110. The second substrate 110 may be formed in a plate shape. That is, the second substrate 110 may be formed of a plate common source line.

In the cell array region 102, a gate stacking structure 120 including cell insulating layers 132 and gate electrode layers 130 alternately stacked on the first surface (e.g., front surface or upper surface) of the second substrate 110, and a first channel structure CH1 extending in a direction crossing the second substrate 110 (e.g., in the third direction Z) through the gate stacking structure 120 may be formed.

In some embodiments, the horizontal conductive layers 112 and 114 may be provided between the second substrate 110 and the gate stacking structure 120 in the cell array region 102. The horizontal conductive layers 112 and 114 may play a role in electrically connecting between the first channel structure CH1 and the second substrate 110. For example, the horizontal conductive layers 112 and 114 may include a first horizontal conductive layer 112 positioned on the first surface of the second substrate 110 and may further include a second horizontal conductive layer 114 positioned on the first horizontal conductive layer 112. In some regions of the connection region 104, the first horizontal conductive layer 112 may not be provided between the second substrate 110 and the gate stacking structure 120, and instead, the horizontal insulating layer 116 may be provided. In the manufacturing process, a part of the horizontal insulating layer 116 may be replaced with the first horizontal conductive layer 112, and another part of the horizontal insulating layer 116 positioned in the connection region 104 may remain in the connection region 104.

The first horizontal conductive layer 112 may function as a part of the common source line of the semiconductor device. For example, the first horizontal conductive layer 112 may function as a common source line together with the second substrate 110.

The first horizontal conductive layer 112 and the second horizontal conductive layer 114 may include, for example, a semiconductor material (e.g., polycrystalline silicon). For example, the first horizontal conductive layer 112 may be a polycrystalline silicon layer doped with impurities, and the second horizontal conductive layer 114 may be a polycrystalline silicon layer doped with impurities or a layer including impurities diffused from the first horizontal conductive layer 112. However, the embodiment is not limited thereto, and the second horizontal conductive layer 114 may be formed of an insulating material. Alternatively, the second horizontal conductive layer 114 may not be separately provided.

A gate stacking structure 120, in which a cell insulating layer 132 and a gate electrode layer 130 are alternately stacked, may be positioned on the second substrate 110 (e.g., on the first horizontal conductive layer 112 and the second horizontal conductive layer 114 formed on the second substrate 110).

In some embodiments, the gate stacking structure 120 may include a plurality of gate stacking structures 120a and 120b which are sequentially stacked on the second substrate 110. Then, the number of gate electrode layers 130 to be stacked may be increased, and thus the number of memory cells may be increased with a stable structure. For example, the gate stacking structure 120 may include the first gate stacking structure 120a and the second gate stacking structure 120b to simplify the structure while increasing data storage capacity. However, the embodiment is not limited thereto, and the gate stacking structure 120 may be composed of one gate stacking structure or may include three or more gate stacking structures.

In the gate stacking structure 120, the gate electrode layer 130 may include a lower gate electrode layer 130L, a memory cell gate electrode layer 130M, and an upper gate electrode layer 130U sequentially positioned on the second substrate 110.

In the first gate stacking structure 120a and the second gate stacking structure 120b, the cell insulating layer 132 may include a gate interlayer insulating layer 132m positioned below the gate electrode layer 130 or between two adjacent gate electrode layers 130 (in the third direction Z), and gate upper insulating layers 132a and 132b positioned above the first gate stacking structure 120a and the second gate stacking structure 120b, respectively. For example, the gate upper insulating layers 132a and 132b may include the first gate upper insulating layer 132a positioned above the first gate stacking structure 120a and the second gate upper insulating layer 132b positioned above the second gate stacking structure 120b. In this case, the first gate upper insulating layer 132a may be an intermediate insulating layer positioned between the first gate stacking structure 120a and the second gate stacking structure 120b (in the third direction Z), and the second gate upper insulating layer 132b may be an uppermost insulating layer positioned at the uppermost portion of the gate stacking structure 120. The second gate upper insulating layer 132b may form a part or the entirety of the cell region insulating layer that is positioned entirely on the top (upper surface) of the cell region 100. In some embodiments, the thickness of the plurality of cell insulating layers 132 (in the third direction Z) may not all be the same. For example, a thickness of the gate upper insulating layers 132a and 132b may be thicker than a thickness of the gate interlayer insulating layer 132m. However, the shape and structure of the cell insulating layer 132 may be variously modified according to embodiments.

The gate electrode layer 130 may include a conductive material. For example, the gate electrode layer 130 may include a metal material such as tungsten (W), copper (Cu), aluminum (Al), and/or the like. In some embodiments, the gate electrode layer 130 may include polycrystalline silicon, metal nitride (e.g., titanium nitride (TiN), tantalum nitride (TaN)), and/or a combination thereof. Although not shown, an insulating layer made of an insulating material may be positioned on (outside) the gate electrode layer 130. The cell insulating layer 132 may include an insulating material. For example, the cell insulating layer 132 may include a low dielectric constant material having a dielectric constant less than that of silicon oxide, silicon nitride, silicon nitride oxide, silicon oxide, or a combination thereof.

In some embodiments, a first channel structure CH1 extending in (e.g., passing through) the gate stacking structure 120 and extending in a direction crossing the second substrate 110 (e.g., a direction perpendicular to the second substrate 110) (a Z-axis direction of the drawing) may be formed. A detailed description of the first channel structure CH1 may be the same as or similar to that described in FIG. 1, and thus may be omitted. That is, the description of the first channel structure CH1 described in FIG. 1 may be equally (or similarly) applied to the first channel structure CH1 of FIG. 11.

A connection region 104 and a second wire part 180 may be provided to connect (e.g., electrically connect) the gate stacking structure 120 and the first channel structure CH1 provided in the cell array region 102 to the circuit region 200 or an external circuit.

The second wire part 180 may include all members electrically connecting the gate electrode 130, the first channel structure CH1, the horizontal conductive layers 112 and 114, and/or the second substrate 110 to the circuit region 200 or an external circuit. For example, the second wire part 180 may include a bit line 182, a gate contact part 184, and a contact via 180a, and a connection wire 190 connecting them.

The bit line 182 may be positioned on the cell insulating layer 132 of the gate stacking structure 120 formed in the cell array region 102. The bit line 182 may extend in an intersecting direction (e.g., the first direction X of the drawing) intersecting one direction in which the gate electrode 130 extends (e.g., the second direction Y). The bit line 182 may be electrically connected to the channel structure CH (e.g., the first channel structure CH1), for example, through the channel pad 144 and a contact via 180a, for example, a bit line contact via.

The connection region 104 may be positioned around the cell array region 102, and a part of the second wire part 180 may be positioned therein. In the connection region 104, a gate electrode 130, horizontal conductive layers 112 and 114, a second substrate 110, and/or a component for connection with the circuit region 200 may be positioned. In addition, the connection region 104 may include an input/output pad and a portion where the input/output connection wire is positioned.

More specifically, the plurality of gate electrodes 130 may extend to position in one direction (Y-axis direction of the drawing or the second direction Y) in the connection region 104, and the extension length of the plurality of gate electrodes 130 may sequentially (and/or discretely) decrease as the distance from the second substrate 110 (in the third direction Z) increases in the connection region 104. For example, a plurality of gate electrodes 130 may be positioned in the connection region 104 while having a step shape. In this case, a plurality of gate electrodes 130 may have a step shape in one direction or a plurality of directions (in the first direction X and/or the second direction Y). In the connection region 104, a plurality of gate contact parts 184 may be electrically connected to a plurality of gate electrodes 130 extending to the connection region 104 passing through the cell insulating layer 132, respectively.

The connection wire 190 may be positioned in the cell array region 102 and/or the connection region 104. The bit line 182 and the gate contact part 184 may be electrically connected to the connection wire 190. For example, the gate contact part 184 may be connected (e.g., electrically connected) to the connection wire 190 through a contact via 180a. In FIG. 11, it is illustrated that the connection wire 190 is provided as a single layer positioned on the same plane as the bit line 182 and the first insulating layer 192 is positioned in a part other than the second wire part 180. For example, an upper surface of the connection wire 190 and an upper surface of the first insulating layer 192 may be coplanar with each other. However, this is only a brief illustration for convenience. Therefore, the connection wire 190 may include a plurality of wire layers for electrical connection with the bit line 182 and the gate contact part 184 and may further include a contact via.

In this way, the bit line 182, the gate electrode 130, the horizontal conductive layers 112 and 114, and/or the second substrate 110 connected (e.g., electrically connected) to the channel structure CH (e.g., the first channel structure CH1) may be electrically connected to the circuit element 220 of the circuit region 200 by the second wire part 180 and the first wire part 230. Referring to FIG. 11, a connection region insulating layer 133 may be positioned in the connection region 104. In addition, an auxiliary layer 134 may be positioned between the connection region insulating layer 133 and the gate electrode 130 (and/or between the connection region insulating layer 133 and the cell insulating layer 132).

The description of the connection region insulating layer 133 and the auxiliary layer 134 described above may be applied in the same (or a similar) manner. The detailed description may be the same as that described in FIG. 1 and FIG. 4 and may therefore be omitted. The connection region insulating layer 133 may include, for example, silicon oxide. For example, the connection region insulating layer 133 may include doped silicon oxide. The connection region insulating layer 133 may be doped with, for example, phosphorus, nitrogen, iron, and/or boron. The auxiliary layer 134 may be positioned as a curved surface at the corner of the gate electrode 130 (and/or the cell insulating layer 132), and the auxiliary layer 134 may include a material different from the connection region insulating layer 133. The auxiliary layer 134 may include, for example, borophosphosilicate glass BPSG, phosphosilicate glass PSG, borosilicate glass BSG, tonen silazene TOSZ, octamethylcyclotetrasiloxane OMCTS, flowable oxide FOx, arsenosilicates AsSG, and/or a combination thereof.

A detailed description of the auxiliary layer 134 may be the same (or similar) as described above.

Hereinafter, a method for manufacturing a semiconductor device according to the present embodiment will be described with reference to the drawings.

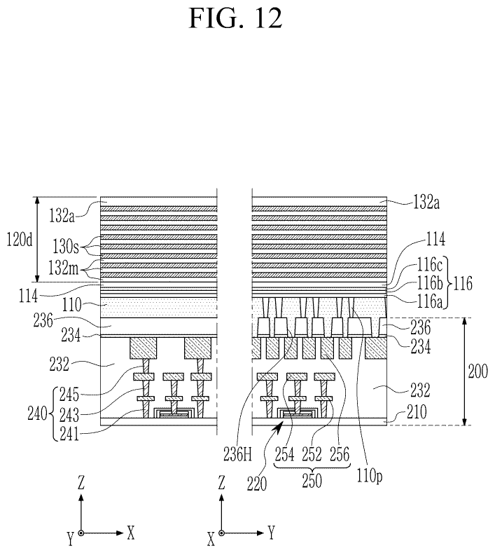

FIGS. 12 to 21 are cross-sectional views illustrating the manufacturing method for a semiconductor device according to some embodiments. Specifically, FIGS. 12 to 21 may be cross-sectional views corresponding to FIG. 1.

First, referring to FIG. 12, a second substrate 110 may be formed on a circuit region 200. The step of forming the second substrate 110 may include a step of patterning the third circuit insulating layer 236 of the circuit region 200 to form a contact hole 236H exposing the third lower wire layer 256 of the circuit region 200, and then forming and patterning the substrate material layer 110a for forming the second substrate 110 on the third circuit insulating layer 236. In the step of depositing the substrate material layer 110a, the contact hole 236H of the third circuit insulating layer 236 may be (at least partially) filled with the substrate material layer 110a.

The substrate material layer 110a and some region of the second substrate 110 connected to the substrate material layer 110a may constitute a part of the gate contact part 184 in a process step to be described later.

The substrate material layer 110a may include, for example, polysilicon doped with impurities.

Subsequently, as the substrate material layer 110a is patterned, the substrate insulating pattern 110p may be formed by filling the region from which a part of the substrate material layer 110a is removed with insulating material.

Subsequently, the horizontal insulating layer 116 and the second horizontal conductive layers 114 may be formed on the second substrate 110.

Specifically, the horizontal insulating layer 116 may be formed on the second substrate 110 by using an insulating material. The horizontal insulating layer 116 may be composed of a single layer or multiple layers. For example, the horizontal insulating layer 116 may include a first horizontal insulating layer 116a, a second horizontal insulating layer 116b, and a third horizontal insulating layer 116c, which are sequentially stacked. For example, each of the first horizontal insulating layer 116a, the second horizontal insulating layer 116b, and the third horizontal insulating layer 116c may include silicon oxide, silicon nitride, and/or silicon oxide. That is, the horizontal insulating layer 116 may have a structure in which a layer made of silicon nitride is positioned between layers made of silicon oxide. At least a part of the horizontal insulating layer 116 may be a layer that is replaced with the first horizontal conductive layer 112 in a subsequent process. That is, the horizontal insulating layer 116 may be formed to include a portion on which the first horizontal conductive layer 112 is to be formed.

Subsequently, the second horizontal conductive layer 114 may be formed on the horizontal insulating layer 116. The second horizontal conductive layer 114 may be formed using a semiconductor material (e.g., polysilicon). For example, the second horizontal conductive layer 114 may include polysilicon doped with impurities.

Subsequently, a first stacking structure 120d, which is a lower structure, may be formed by alternately stacking a plurality of interlayer insulating layers 132m and a plurality of sacrificial insulating layers 130s on the second horizontal conductive layer 114. The interlayer insulating layers 132m and the sacrificial insulating layers 130s may be alternately stacked. The first gate upper insulating layer 132a may be formed on the sacrificial insulating layer 130s positioned at the uppermost portion among the plurality of sacrificial insulating layers 130s.

By the etching process after stacking, the first stacking structure 120d may have a step shape in a cross section in the connection region 104. However, the step shape of the first stacking structure 120d is not shown in the cross section of FIG. 12.

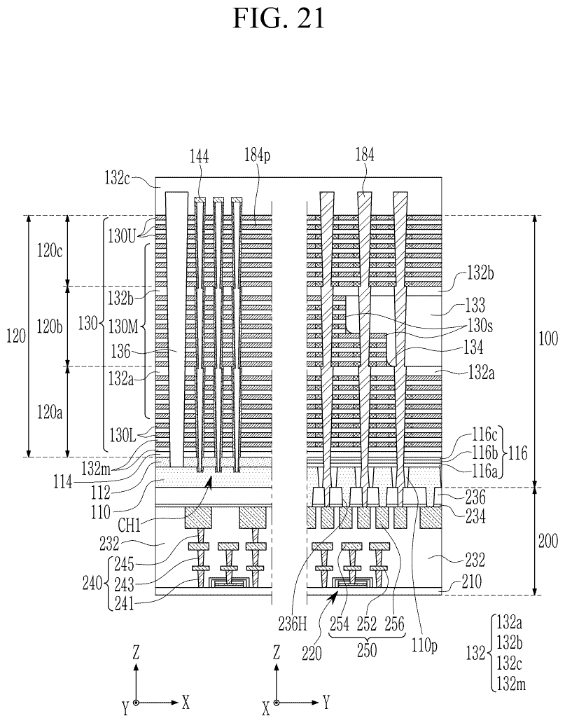

The sacrificial insulating layer 130s may be formed of a different material from that of the interlayer insulating layer 132m. The interlayer insulating layer 132m may include, for example, silicon oxide, silicon nitride, silicon nitride oxide, a low dielectric constant material, and/or the like, and the sacrificial insulating layer 130s may include, for example, silicon, silicon oxide, silicon carbide, and/or silicon nitride, and may be formed of a different material from the interlayer insulating layer 132m. For example, the interlayer insulating layer 132m may include silicon oxide, and the sacrificial insulating layer 130s may include silicon nitride. The sacrificial insulating layer 130s may be a layer which is replaced with a gate electrode (130 of FIG. 21) in a subsequent process. That is, the sacrificial insulating layer 130s may be formed to correspond to a portion where a gate electrode (130 of FIG. 21) is to be formed.

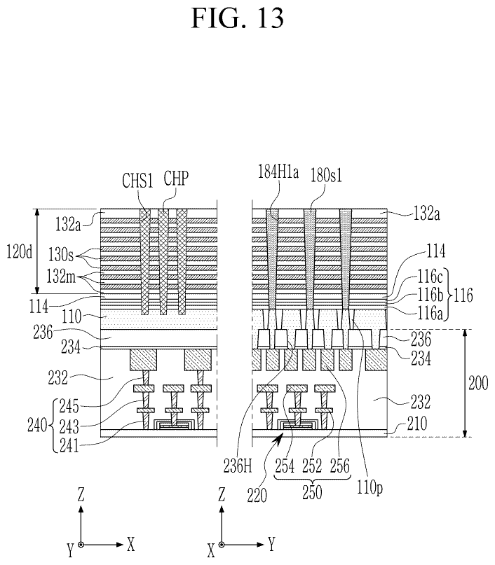

Next, referring to FIG. 13, by patterning the first stacking structure 120d, a first sub-channel hole CHS1 extending in (e.g., passing through) the first stacking structure 120d may be formed in a region corresponding to the cell array region 102, and a first sub-through gate contact hole 184H1a extending in (e.g., passing through) the first stacking structure 120d may be formed in a region corresponding to the connection region 104.

The first sub-channel hole CHS1 may pass through the second horizontal conductive layer 114 and the horizontal insulating layer 116 may pass through may not pass through the second substrate 11-0. That is, the depth (in the third direction Z) of the first sub-channel hole CHS1 formed in the second substrate 110 may be thinner than the thickness of the second substrate 110 (in the third direction Z). For example, the first sub-channel hole CHS1 may extend into at least a portion of the second substrate 110. The first sub-channel hole CHS1 may be formed to correspond to a region in which the first channel structure CH1 of FIG. 1 is formed. The first sub-through gate contact hole 184H1a may pass through the second horizontal conductive layer 114 and the horizontal insulating layer 116 and may not pass through the second substrate 110. For example, the first sub-through gate contact hole 184H1a may extend into a portion of the second substrate 110. The first sub-through gate contact hole 184H1a may be formed in a region of the second substrate 110 connected to the third lower wire layer 256 through a contact hole 236H formed in the third circuit insulating layer 236 of the circuit region 200. That is, the first sub-through gate contact hole 184H1a may be formed to correspond to a region in which the gate contact part 184 of FIG. 1 is formed.

Subsequently, a channel sacrificial pattern CHP may be formed in the first sub-channel hole CHS1, and a first contact part sacrificial pattern 180s1 may be formed in the first sub-through gate contact hole 184H1a. The channel sacrificial pattern CHP may include, for example, polysilicon, and the first contact part sacrificial pattern 180s1 may include, for example, a carbon-based material. However, materials included in the channel sacrificial pattern CHP and the first contact part sacrificial pattern 180s1 are not limited thereto, and may be variously changed.

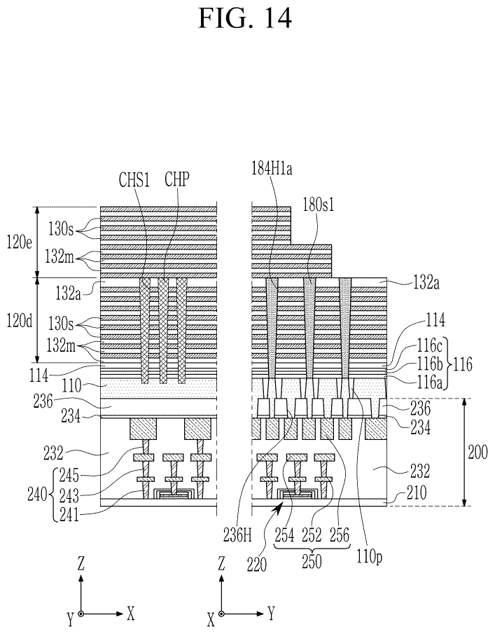

Next, referring to FIG. 14, a second stacking structure 120e may be formed by alternately stacking a plurality of interlayer insulating layers 132m and a plurality of sacrificial insulating layers 130s. A method of manufacturing the sacrificial insulating layer 130s and the interlayer insulating layer 132m of the second stacking structure 120e may be (substantially) the same as the case of the first stacking structure 120d, and a description thereof may be omitted. By the etching process after stacking, the second stacking structure 120d may have a step shape in a cross section in the connection region 104.

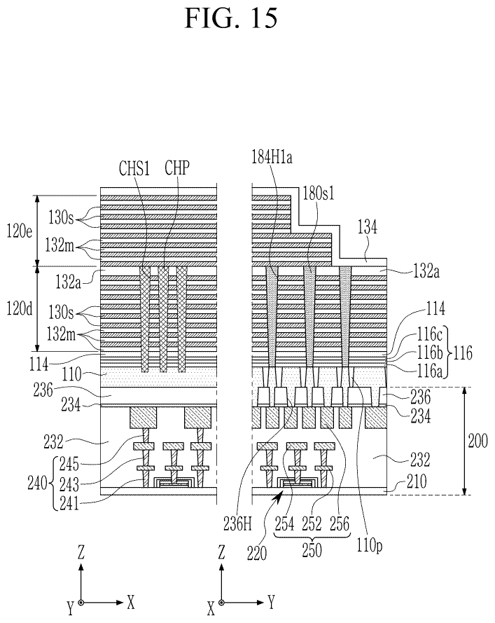

Next, referring to FIG. 15, an auxiliary layer 134 may be formed. The description of the auxiliary layer 134 described above may be applied in the same (or a similar) manner. That is, the auxiliary layer 134 may include a different material from that of the connection region insulating layer 133, and may include, for example, a flowable material. The auxiliary layer 134 may include borophosphosilicate glass BPSG, phosphosilicate glass PSG, borosilicate glass BSG, tonen silazene TOSZ, octamethylcyclotetrasiloxane OMCTS, flowable oxide FOx, arsenosilicates AsSG or a combination thereof. However, it is not limited to the materials illustrated above, and any material (any material compatible with other processes) that has a gentle angle through heat treatment after deposition may be used.

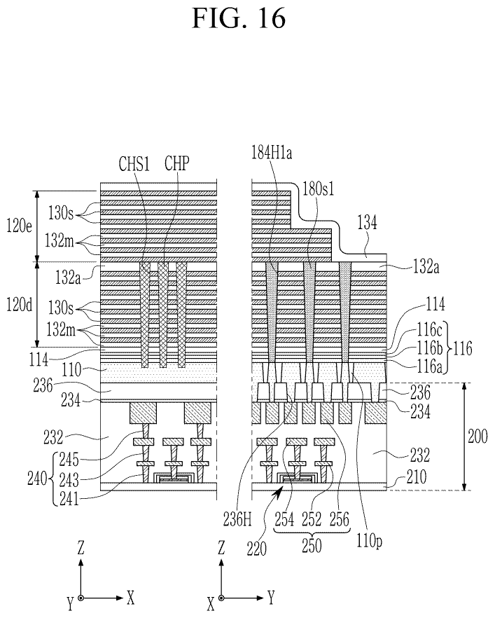

As shown in FIG. 15, the auxiliary layer 134 may be on (formed to cover) the (exposed) upper surface and (the exposed) side surfaces of the interlayer insulating layer 132m and the sacrificial insulating layer 130s. Next, referring to FIG. 16, the auxiliary layer 134 may be heat-treated. The description of the heat treatment process described in FIGS. 5 to 7 may be applied in the same (or a similar) manner. That is, the heat treatment time may be, for example, (about) 20 minutes to (about) 3 hours.

The heat treatment temperature may vary depending on the material of the auxiliary layer 134. For example, when the auxiliary layer 134 includes a flowable oxide FOx, the heat treatment temperature may be (about) 200° C. to (about) 250° C. In addition, when the auxiliary layer 134 includes PSG, the heat treatment temperature may be (about) 1000° C. to (about) 1100° C. In addition, when the auxiliary layer 134 includes BPSG, the heat treatment temperature may be (about) 800° C. to (about) 950° C.

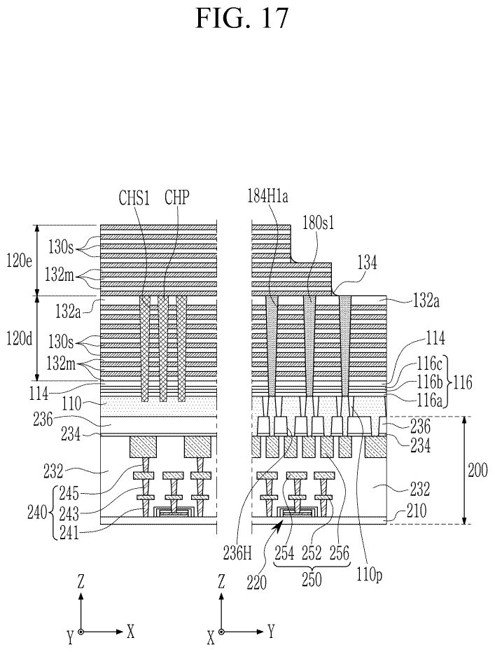

In this heat treatment process, the corner of the auxiliary layer 134 may be smooth and a curved surface may be formed. Next, referring to FIG. 17, the auxiliary layer 134 may be etched. In this case, etching of the auxiliary layer 134 may be performed by isotropic etching. In this step, the auxiliary layer 134 may remain unetched at a point where the side surface of the interlayer insulating layer 132m and the sacrificial insulating layer 130s and the upper surface of the sacrificial insulating layer 130s (or the upper surface of the first gate upper insulating layer 132a) meet. Since the auxiliary layer 134 has a curved surface due to the heat treatment process of the auxiliary layer 134 in the previous step, the shape of the auxiliary layer 134 remaining by etching in this step may also be a curved surface. In this case, the auxiliary layer 134 may be formed of a concave curved surface (toward the corner where the side surface of the interlayer insulating layer 132m and the sacrificial insulating layer 130s and the upper surface of the sacrificial insulating layer 130s (or the upper surface of the first gate upper insulating layer 132a) meet).

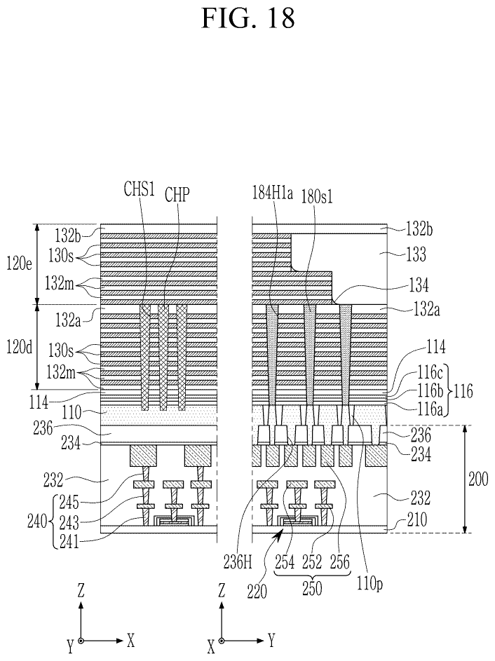

Next, referring to FIG. 18, the connection region insulating layer 133 may be formed in the connection region 104. The description of the connection region insulating layer 133 described above may be applied in the same (or a similar) manner. The connection region insulating layer 133 may include, for example, silicon oxide. For example, the connection region insulating layer 133 may include doped silicon oxide. The connection region insulating layer 133 may be doped with, for example, phosphorus, nitrogen, iron, and/or boron.

The connection region insulating layer 133 may be formed by plasma chemical vapor deposition PECVD. Since the auxiliary layer 134 is formed at a point where the side surfaces of the interlayer insulating layer 132m and the sacrificial insulating layer 130s and the upper surface of the sacrificial insulating layer 130s (or the upper surface of the first gate upper insulating layer 132a) meet, the occurrence of defects between the connection region insulating layer 133 formed on the side surfaces of the interlayer insulating layer 132m and the sacrificial insulating layer 130s and the connection region insulating layer 133 formed on the upper surface of the sacrificial insulating layer 130s (or the upper surface of the first gate upper insulating layer 132a) may be reduced (e.g., minimized).

Next, the second gate upper insulating layer 132b may be formed on the connection region insulating layer 133.

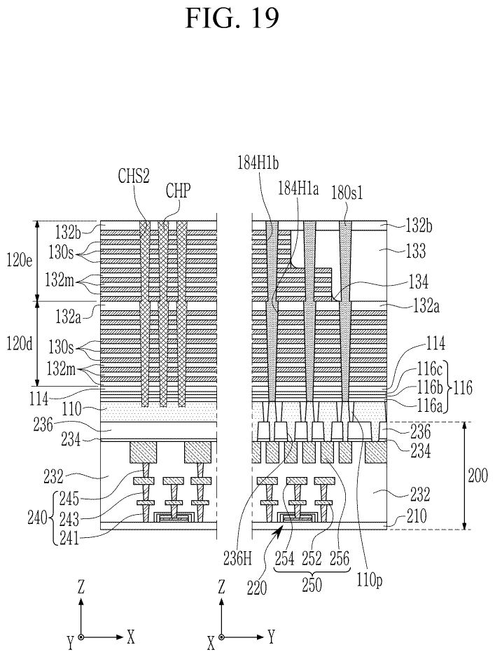

Next, referring to FIG. 19, the second stacking structure 120e may be patterned to form a second sub-channel hole CHS2 extending in (e.g., passing through) the second stacking structure 120e in the region corresponding to the cell array region 102. The second sub-channel hole CHS2 may be formed to overlap the first sub-channel hole CHS1 (in the third direction Z). As the second sub-channel hole CHS2 is formed, at least a portion of the channel sacrificial pattern CHP formed in the first sub-channel hole CHS1 may be exposed.

Furthermore, by patterning the second stacking structure 120e, a second sub-through gate contact hole 184H1b extending in (e.g., passing through) the second stacking structure 120e and the second gate upper insulating layer 132b may be formed in a region corresponding to the connection region 104.

The second sub-through gate contact hole 184H1b may be formed to overlap the first sub-through gate contact hole 184H1a (in the third direction Z).

Subsequently, a channel sacrificial pattern CHP may be formed in the second sub-channel hole CHS2, and a first contact part sacrificial pattern 180s1 may be formed in the second sub-through gate contact hole 184H1b.

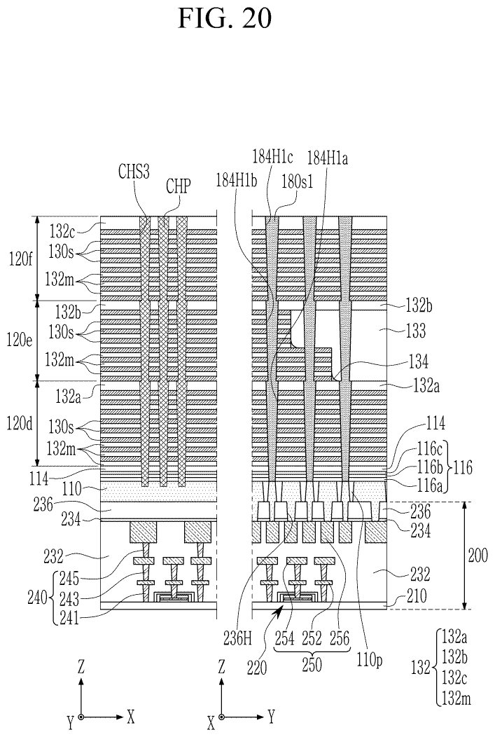

Subsequently, referring to FIG. 20, a third stacking structure 120f may be formed by alternately stacking a plurality of interlayer insulating layers 132m and a plurality of sacrificial insulating layers 130s on the second stacking structure 120e. Thereafter, the third gate upper insulating layer 132c may be formed. Subsequently, the third stacking structure 120f may be patterned to form a third sub-channel hole CHS3 extending in (e.g., passing through) the third stacking structure 120f in a region corresponding to the cell array region 102. The third sub-channel hole CHS3 may be formed to overlap the second sub-channel hole CHS2 (in the third direction Z). As the third sub-channel hole CHS3 is formed, at least a portion of the channel sacrificial pattern CHP formed in the second sub-channel hole CHS2 may be exposed.

The third sub-through gate contact hole 184H1c may be formed to overlap the second sub-through gate contact hole 184H1b (in the third direction Z).

Subsequently, a channel sacrificial pattern CHP may be formed in the third sub-channel hole CHS3, and a first contact part sacrificial pattern 180s1 may be formed in the third sub-through gate contact hole 184H1c.

Each of the first, second, and third sub-through gate contact holes 184H1a, 184H1b, and 184H1c may have a shape in which a width thereof (in the first direction X and/or the second direction Y) gradually decreases from an upper portion (e.g., a farther portion from the second substrate 110) to a lower portion (e.g., a closer portion to the second substrate 110).

For example, the width of the upper portion of the first sub-through gate contact hole 184H1a may be greater than the width of the lower portion of the second sub-through gate contact hole 184H1b, and the width of the upper portion of the second sub-through gate contact hole 184H1b may be greater than the width of the lower portion of the third sub-through gate contact hole 184H1c.

Accordingly, the widths of the first, second, and third sub-through gate contact holes 184H1a, 184H1b, and 184H1c overlapping each other (in the third direction Z) may have a form where the width gradually decreases from the uppermost side, then increases, and then gradually decreases again. That is, a bent part or a step may be included at a boundary of each of the first, second, and third sub-through gate contact holes 184H1a, 184H1b, and 184H1c.

Next, referring to FIG. 21, in the region corresponding to the cell array region 102, the first channel structure CH1 may be formed in the hole formed by removing the channel sacrificial pattern CHP positioned in the first, second, and third sub-channel holes CHS1, CHS2, and CHS3. For example, a first gate dielectric layer (see 146 in FIG. 2), a first channel layer (see 140 in FIG. 2), and a first core insulating layer (see 142 in FIG. 2) may be sequentially formed to (at least partially) fill the hole formed by removing the channel sacrificial pattern CHP, and a first channel structure CH1 may be formed by forming a first channel pad (see 144 in FIG. 2) covering (overlapping in the third direction Z) the first gate dielectric layer 146, the first channel layer 140, and/or the first core insulating layer 142. Furthermore, in the region corresponding to the connection region 104, the first contact part sacrificial patterns 180s1 positioned in the first, second, and third sub-through gate contact holes 184H1a, 184H1b, 184H1c in FIG. 20 are removed, and a conductive material such as tungsten (W), copper (Cu), aluminum (Al) may be positioned (embedded) in the removed region to form a gate contact part 184.

Subsequently, the gate stacking structure 120 may be formed by replacing the sacrificial insulating layer 130s with the gate electrode 130.

First, an opening part may be formed in a region corresponding to the separation structure (136 in FIG. 1) to extend in (e.g., pass through) the first to third gate stacking structures 120a, 120b, and 120c in the third direction Z. The side surface of each layer constituting the first, second, and third gate stacking structures 120a, 120b, and 120c may be exposed through the opening part.

The opening part may be formed to pass through all layers constituting the first, second, and third gate stacking structures 120a, 120b, and 120c. In addition, the opening part may extend in (e.g., pass through) the second horizontal conductive layer 114 and the horizontal insulating layer 116 (in the third direction Z). The gate stacking structures 120 adjacent to each other may be separated by the opening part.

Subsequently, the horizontal insulating layer 116 may be removed through the opening part, and the first horizontal conductive layer 112 may be formed in the space from which the horizontal insulating layer 116 is removed. The first horizontal conductive layer 112 may be positioned between the second substrate 110 and the second horizontal conductive layer 114 in the third direction Z. The first horizontal conductive layer 112 may include, for example, polysilicon doped with impurities. The first horizontal conductive layer 112 may function as a common source line together with the second substrate 110 and the second horizontal conductive layer 114.

Subsequently, as the sacrificial insulating layer 130s is selectively removed by an etching process (for example, a wet etching process) through the opening part, a gate stacking structure 120 including the first, second, and third gate stacking structures 120a, 120b, and 120c may be formed.

Specifically, the sacrificial insulating layer 130s may be removed first, and the gate electrode 130 may be formed in a space from which the sacrificial insulating layer 130s is removed. That is, after removing the sacrificial insulating layer 130s by using an etching process, the gate electrode 130 may be formed by depositing a metal material such as tungsten (W), copper (Cu), aluminum (Al), and/or the like. The gate electrode 130 may include a lower gate electrode 130L, a memory cell gate electrode 130M, and an upper gate electrode 130U sequentially positioned from (on) the second substrate 110.

Next, referring to FIG. 1, a third gate upper insulating layer 132c may be formed on the channel pad 144, the gate contact part 184, the source contact part 186, and the through contact part 188, and a bit line 182 and a connection wire 191 may be formed on the third gate upper insulating layer 132c. The bit line 182 and the channel pad 144 may be connected (e.g., electrically connected) by a contact via 180a. The source contact part 186 and the through contact part 188 may be connected (e.g., electrically connected) to the connection wire 191 by a contact via 180a.

Next, an electronic system including a semiconductor device according to some embodiments will be described with reference to FIG. 22.

FIG. 22 is a schematic view illustrating an electronic system including a semiconductor device according to some embodiments.

As shown in FIG. 22, an electronic system 1000 according to some embodiments may include a semiconductor device 1100 and a controller 1200 electrically connected to the semiconductor device 1100. The electronic system 1000 may be, for example, a storage device including one or a plurality of semiconductor devices 1100 or an electronic device including the storage device. For example, the electronic system 1000 may be, for example, a solid-state drive device SSD, a universal serial bus USB, a computing system, a medical device, or a communication device including one or more semiconductor devices 1100.

The semiconductor device 1100 may be a nonvolatile memory device, for example, a NAND flash memory device. The semiconductor device 1100 may include a first structure 1100F and a second structure 1100S on the first structure 1100F. In some embodiments, the first structure 1100F may be positioned next to (adjacent) the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, a first gate upper line UL1, a second gate lower line UL2, a first gate lower line LL1, a second gate lower line LL2, and a memory cell string CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT positioned between the lower transistors LT1 and LT2 and the upper transistors UT1 and UT2. The number of lower transistors LT1 and LT2 and the number of upper transistors UT1 and UT2 may be variously changed according to an embodiment.

In some embodiments, the lower transistors LT1 and LT2 may include a ground selection transistor, and the first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through the first connection wire 1115 extending between the first structure 1100F and the second structure 1100S. The bit line BL may be electrically connected to the page buffer 1120 through a second connection wire 1125 extending between the first structure 1100F and the second structure 1100S.

In the first structure 1100F, the decoder circuit 1110 and the page buffer 1120 may perform a control operation on at least one memory cell transistor selected from a plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pad 1101 may be electrically connected to the logic circuit 1130 through an input/output connection wire 1135 extending between the first structure 1100F and the second structure 1100S.

The controller 1200 may include a processor 1210, a NAND controller 1220, and a host interface 1230. According to some embodiments, the electronic system 1000 may include a plurality of semiconductor devices 1100, and in this case, the controller 1200 may control the plurality of semiconductor devices 1100.

The processor 1210 may control the overall operation of the electronic system 1000 including the controller 1200. The processor 1210 may operate according to predetermined firmware and may access the semiconductor device 1100 by controlling the NAND controller 1220. The NAND controller 1220 may include a NAND interface 1221 that processes communication with the semiconductor device 1100. Through the NAND interface 1221, a control command for controlling the semiconductor device 1100, a data to be recorded in the memory cell transistor MCT of the semiconductor device 1100, a data to be read from the memory cell transistor MCT of the semiconductor device 1100, and the like may be transmitted. The host interface 1230 may provide a communication function between the electronic system 1000 and an external host. When a control command is received from an external host through the host interface 1230, the processor 1210 may control the semiconductor device 1100 in response to the control command.

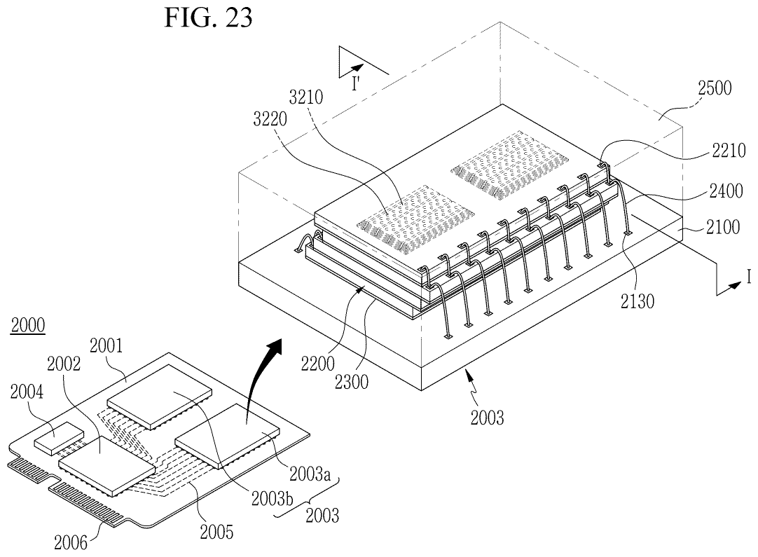

FIG. 23 is a perspective view schematically illustrating an electronic system including a semiconductor device according to some embodiments.

As shown in FIG. 23, an electronic system 2000 according to some embodiments may include a main substrate 2001, a controller 2002 (mounted) on the main substrate 2001, one or more semiconductor packages 2003, and a DRAM 2004. The semiconductor package 2003 and the DRAM 2004 may be connected (e.g., electrically connected) to the controller 2002 by a wire pattern 2005 formed on the main substrate 2001.

The main substrate 2001 may include a connector 2006 including a plurality of pins that are configured to be connected to an external host. The number and arrangement of the plurality of pins in the connector 2006 may vary depending on the communication interface between the electronic system 2000 and the external host. In some embodiments, the electronic system 2000 may communicate with an external host according to interfaces such as Universal Serial Bus (USB), Peripheral Component Interconnect Express (PCI-Express), Serial Advanced Technology Attachment (SATA), and/or M-Phy for Universal Flash Storage (UFS). In some embodiments, the electronic system 2000 may operate by power supplied from an external host via connector 2006. The electronic system 2000 may further include a power management integrated circuit PMIC that distributes power supplied from the external host to the controller 2002 and the semiconductor package 2003.

The controller 2002 may record data in the semiconductor package 2003 or read data from the semiconductor package 2003 and may improve the operation speed of the electronic system 2000.

The DRAM 2004 may be a buffer memory for alleviating a speed difference between the semiconductor package 2003 which is a data storage space and an external host. The DRAM 2004 included in the electronic system 2000 may operate as a kind of cache memory and may provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a semiconductor chip 2200 on the package substrate 2100, an adhesive layer 2300 positioned on the lower surface of each of the semiconductor chips 2200, a connection structure 2400 electrically connecting the semiconductor chip 2200 to the package substrate 2100, and a molding layer 2500 on (e.g., covering) the semiconductor chip 2200 and the connection structure 2400 on the package substrate 2100.

The package substrate 2100 may be a printed circuit board PCB including a package upper pad 2130. Each semiconductor chip 2200 may include an input/output pad 2210. The input/output pad 2210 may correspond to the input/output pad 1101 of FIG. 22. Each of the semiconductor chips 2200 may include a gate stacking structure 3210 and a channel structure 3220. The semiconductor chip 2200 may include the semiconductor device described above (e.g., the semiconductor device illustrated in FIG. 1).

In some embodiments, the connection structure 2400 may be a bonding wire electrically connecting the input/output pad 2210 to the package upper pad 2130. Therefore, in each of the first and the second semiconductor packages 2003a and 2003b, the semiconductor chips 2200 may be electrically connected to each other in a bonding wire manner and may be electrically connected to the package upper pad 2130 of the package substrate 2100. Depending on the embodiment, in each of the first and second semiconductor packages 2003a and 2003b, the semiconductor chip 2200 may be electrically connected to each other by a connection structure including a through electrode (e.g., Through Silicon Via (TSV)) instead of a connection structure 2400 that is a bonding wire.

In some embodiments, the controller 2002 and the semiconductor chip 2200 may be included in one package. For example, the controller 2002 and the semiconductor chip 2200 may be (mounted) on a separate interposer substrate different from the main substrate 2001, and the controller 2002 and the semiconductor chip 2200 may be connected (e.g., electrically connected) to each other by a wire formed on the interposer substrate.

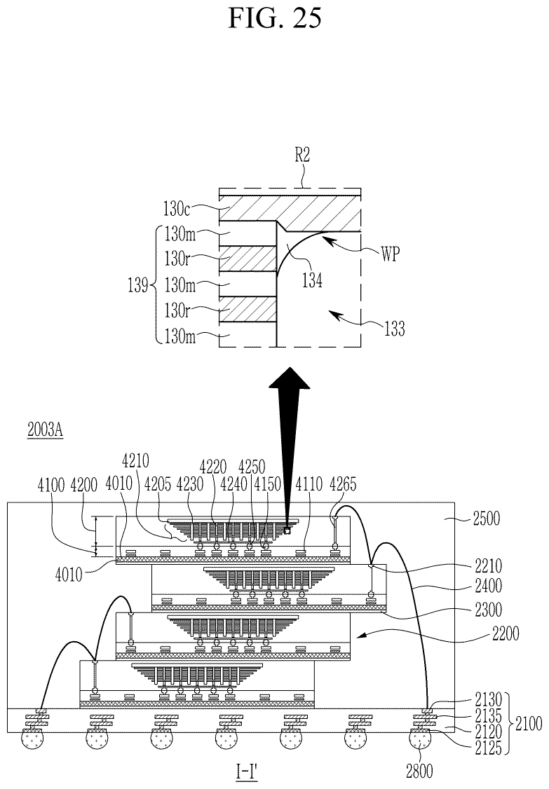

FIGS. 24 and 25 are cross-sectional views schematically illustrating a semiconductor package according to some embodiments. FIGS. 24 and 25 may be embodiments of the semiconductor package 2003 of FIG. 23, and conceptually show a region taken along the cutting line I-I′ of the semiconductor package 2003 of FIG. 23. Referring to FIG. 24, in the semiconductor package 2003, the package substrate 2100 may be a printed circuit board PCB. The package substrate 2100 may include a package substrate body 2120, a package upper pad 2130 positioned on the upper surface of the package substrate body 2120, a lower pad 2125 positioned on the lower surface of the package substrate body 2120 or exposed through the lower surface, and an internal wire 2135 electrically connecting the upper pad 2130 and the lower pad 2125 inside the package substrate body 2120. The upper pad 2130 may be electrically connected to the connection structure 2400. The lower pad 2125 may be connected (e.g., electrically connected) to the wire pattern 2005 of the main substrate 2001 of the electronic system 2000 through the conductive connection part 2800 as shown in FIG. 23. The semiconductor chip 2200 may include a first structure 3100 and a semiconductor substrate 3010. The first structure 3100 may be on the semiconductor substrate 3010. The first structure 3100 may include a peripheral circuit region including the peripheral wire 3110. A second structure 3200 on the first structure 3100 may include a common source line 3205, a gate stacking structure 3210 on the common source line 3205, a channel structure 3220 and a separation structure 3230 passing through the gate stacking structure 3210, a bit line 3240 electrically connected to the channel structure 3220, and a gate connection wire electrically connected to the word line of the gate stacking structure 3210.

In the semiconductor chip 2200 or the semiconductor device 1100 according to some embodiments, the auxiliary layer 134 may be positioned on the side surface of the gate electrode 130 (and/or the cell insulating layers 132) and/or an upper surface of the connection gate electrode 130c. The description of the auxiliary layer 134 described above may be applied in the same (or a similar) manner. That is, the auxiliary layer 134 may include a different material from that of the connection region insulating layer 133, and may include, for example, a flowable material. The flowable material means a material having flowability during heat treatment after deposition. The auxiliary layer 134 may include, for example, borophosphosilicate glass (BPSG), phosphosilicate glass (PSG), borosilicate glass (BSG), tonen silazene (TOSZ), octamethylcyclotetrasiloxane (OMCTS), flowable Oxide (Fox), arsenosilicates (AsSG) and/or a combination thereof. However, it is not limited to the materials illustrated above, and any material (compatible with other processes) that has flowability and a gentle angle through heat treatment after deposition may be used.

The auxiliary layer 134 may be formed at the corner of the step structure 139 and may be formed as a curved surface. In this case, the auxiliary layer 134 may be formed as a concave curved surface with respect to (toward) the corner of the step structure 139. This auxiliary layer 134 may solve (reduce) the problem that the connection region insulating layer 133 is not uniformly formed in the process of forming the connection region insulating layer 133.

Each of the semiconductor chips 2200 may include a through wire 3245 electrically connected to the peripheral wire 3110 of the first structure 3100 and extending into the second structure 3200. The through wire 3245 may extend in (e.g., may pass through) the gate stacking structure 3210 or may be further positioned outside the gate stacking structure 3210. Each of the semiconductor chips 2200 may further include an input/output connection wire 3265 electrically connected to the peripheral wire 3110 of the first structure 3100 and extending in the second structure 3200 and an input/output pad 2210 electrically connected to the input/output connection wire 3265.

In some embodiments, a plurality of semiconductor chips 2200 in the semiconductor package 2003 may be electrically connected to each other by a connection structure 2400 in the form of a bonding wire. In some embodiments, a plurality of semiconductor chips 2200 or a plurality of portions constituting the semiconductor chips 2200 may be electrically connected to each other by a connection structure including a through electrode TSV (e.g., Through Silicon Via, (TSV)).

Referring to FIG. 25, in the semiconductor package 2003A, each of the semiconductor chips 2200 may include a semiconductor substrate 4010, a first structure 4100 on the semiconductor substrate 4010, and a second structure 4200 bonded to the first structure 4100 by a wafer bonding method on the first structure 4100. The first structure 4100 may include a peripheral circuit region including the peripheral wire 4110 and the first bonding structure 4150. The second structure 4200 may include a common source line 4205, a gate stacking structure 4210 between the common source line 4205 and the first structure 4100, a channel structure 4220 and a separation structure 4230 extending in (e.g., passing through) the gate stacking structure 4210, and a second bonding structure 4250 electrically connected to the channel structure 4220 and the word line of the gate stacking structure 4210, respectively. For example, the second bonding structure 4250 may be electrically connected to the channel structure 4220 and the word line WL, respectively, through a bit line 4240 electrically connected to the channel structure 4220 and a gate connection wire electrically connected to the word line WL. The first bonding structure 4150 of the first structure 4100 and the second bonding structure 4250 of the second structure 4200 may be bonded while being in contact with each other. The bonded portions of the first bonding structure 4150 and the second bonding structure 4250 may be formed of, for example, copper (Cu).

In the semiconductor chip 2200 or the semiconductor device 1100 according to some embodiments, the auxiliary layer 134 may be positioned on the side surface of the gate electrode 130 (and/or the cell insulating layers 132) and/or lower surface of the connection gate electrode 130c. The description of the auxiliary layer 134 described above may be applied in the same (or a similar) manner. That is, the auxiliary layer 134 may include a different material from that of the connection region insulating layer 133, and may include, for example, a flowable material. The flowable material may mean a material having flowability during heat treatment after deposition. The auxiliary layer 134 may include borophosphosilicate glass (BPSG), phosphosilicate glass (PSG), borosilicate glass (BSG), tonen silazene (TOSZ), octamethylcyclotetrasiloxane (OMCTS), flowable Oxide (Fox), arsenosilicates (AsSG) and/or a combination thereof. However, it is not limited to the materials illustrated above, and any material (any material compatible with other processes) that has flowability and a gentle angle through heat treatment after deposition may be used.

The auxiliary layer 134 may be formed at the corner of the step structure 139 and may be formed as a curved surface. In this case, the auxiliary layer 134 may be formed as a concave curved surface with respect to (toward) the corner of the step structure 139. This auxiliary layer 134 may reduce (solve) the problem that the connection region insulating layer 133 is not uniformly formed in the process of forming the connection region insulating layer 133. Each of the semiconductor chips 2200 may further include an input/output pad 2210 and an input/output connection wire 4265 under the input/output pad 2210. The input/output connection wire 4265 may be electrically connected to a part of the second bonding structure 4250.

In some embodiments, a plurality of semiconductor chips 2200 in the semiconductor package 2003A may be electrically connected to each other by a connection structure 2400 in the form of a bonding wire. In some embodiments, a plurality of semiconductor chips 2200 or a plurality of portions constituting the semiconductor chips 2200 may be electrically connected by a connection structure including a through electrode.

Although example embodiments have been described in detail above, the scope of the present invention is not limited to this, various modifications and improvements of a person of an ordinary skill in the art using the basic concept of the present invention defined in the following claim range also belong to the scope of the present invention.

What is claimed is:

1. A semiconductor device comprising:
a substrate;
a circuit region that includes a peripheral circuit structure on the substrate; and
a cell region on the circuit region, wherein the cell region includes a cell array region and a connection region adjacent the cell array region,
wherein the cell region further includes:
a gate stacking structure that includes interlayer insulating layers and gate electrodes that are alternately stacked on the substrate;
a channel structure that extends in the gate stacking structure in the cell array region;
a gate contact part that is electrically connected to the gate electrodes of the gate stacking structure in the connection region; and
an auxiliary layer that is in contact with the gate stacking structure in the connection region,
wherein the gate stacking structure has a step structure in a cross-sectional view in the connection region,
wherein the auxiliary layer is at a corner of the step structure,
wherein the auxiliary layer has a curved surface, and
wherein the auxiliary layer includes a first material that includes boron, phosphorus, nitrogen, and/or iron.

2. The semiconductor device of claim 1, wherein the auxiliary layer has a concave shape toward the corner of the step structure.

3. The semiconductor device of claim 1, wherein the first material includes borophosphosilicate glass (BPSG), phosphosilicate glass (PSG), borosilicate glass (BSG), tonen silazene (TOSZ), octamethylcyclotetrasiloxane (OMCTS), and/or arsenosilicates (AsSG).

4. The semiconductor device of claim 1, wherein the auxiliary layer is on an upper surface and a side surface of the step structure, and
the curved surface is on the upper surface and the side surface of the step structure.

5. The semiconductor device of claim 4, wherein a width of the auxiliary layer in a direction is 20 nm to 120 nm, and
wherein the direction is parallel with an upper surface of the substrate.

6. The semiconductor device of claim 4, wherein a thickness of the auxiliary layer in a direction is 20 nm to 120 nm, and
wherein the direction is perpendicular to an upper surface of the substrate.

7. The semiconductor device of claim 1, further comprising:
a connection region insulating layer in the connection region,
wherein the connection region insulating layer is on the auxiliary layer.

8. The semiconductor device of claim 7, wherein the connection region insulating layer includes a silicon oxide doped with phosphorus, nitrogen, iron, and/or boron.

9. The semiconductor device of claim 7, wherein the connection region insulating layer includes a second material, and
the first material is different from the second material.

10. The semiconductor device of claim 1, wherein the gate stacking structure includes a portion in the connection region,
wherein the portion is spaced apart from the auxiliary layer in a direction that is parallel with an upper surface of the substrate, and
wherein the auxiliary layer is spaced apart from the gate contact part in the direction.

11. The semiconductor device of claim 1, wherein the gate contact part extends in the gate stacking structure to be electrically connected to the circuit region in the connection region, electrically connected to a gate electrode among the gate electrodes, and electrically insulated from remaining gate electrodes among the gate electrodes with insulating patterns therebetween.

12. A method of manufacturing a semiconductor device comprising:
forming a stacking structure by alternately stacking sacrificial insulating layers and insulating layers in a circuit region that includes a peripheral circuit structure;
depositing an auxiliary layer on an upper surface of the stacking structure;
heat-treating the auxiliary layer to alleviate an angle of the auxiliary layer; and
etching the auxiliary layer,
wherein a part of the auxiliary layer includes a curved surface at a corner of the stacking structure.

13. The method of manufacturing the semiconductor device of claim 12, wherein the auxiliary layer includes a concave curved surface toward the corner of the stacking structure.

14. The method of manufacturing the semiconductor device of claim 12, wherein the auxiliary layer includes borophosphosilicate glass (BPSG), phosphosilicate glass (PSG), borosilicate glass (BSG), tonen silazene (TOSZ), octamethylcyclotetrasiloxane (OMCTS), and/or arsenosilicate (AsSG).

15. The method of manufacturing the semiconductor device of claim 12, further comprising: forming a connection region insulating layer after the etching the auxiliary layer, and
wherein the connection region insulating layer includes silicon oxide doped with phosphorus, nitrogen, iron, and/or boron.

16. The method of manufacturing the semiconductor device of claim 15, wherein the auxiliary layer includes a first material, and the connection region insulating layer includes a second material, and
wherein the first material is different from the second material.

17. The method of manufacturing the semiconductor device of claim 15, further comprising:
forming a channel structure that extends in the stacking structure and a gate contact part that extends in the connection region insulating layer, and
wherein the gate contact part is spaced part from the auxiliary layer in a horizontal direction.

18. The method of manufacturing the semiconductor device of claim 12, wherein the stacking structure has a portion that is spaced apart from the auxiliary layer in a horizontal direction.

19. An electronic system comprising:
a main substrate;
a semiconductor device on the main substrate; and
a controller electrically connected to the semiconductor device on the main substrate,
wherein the semiconductor device includes:
a substrate;
a circuit region that includes a peripheral circuit structure on the substrate; and
a cell region on the circuit region, wherein the cell region includes a cell array region and a connection region adjacent the cell array region,
wherein the cell region further includes:
a gate stacking structure that includes interlayer insulating layers and gate electrodes that are alternately stacked on the substrate;
a channel structure that extends in the gate stacking structure in the cell array region;
a gate contact part that is electrically connected to the gate electrodes of the gate stacking structure in the connection region; and
an auxiliary layer that is in contact with the gate stacking structure in the connection region,
wherein the gate stacking structure has a step structure in a cross-sectional view in the connection region, and
wherein the auxiliary layer is at a corner of the step structure,
wherein the auxiliary layer has a curved surface, and
wherein the auxiliary layer includes a material that includes boron, phosphorus, nitrogen, and/or iron.

20. The electronic system of claim 19, wherein the material includes borophosphosilicate glass (BPSG), phosphosilicate glass (PSG), borosilicate glass (BSG), tonen silazene (TOSZ), octamethylcyclotetrasiloxane (OMCTS), and/or arsenosilicate (AsSG).
